(19) United States
(12) Patent Application Publication
(10) Pub. No.: US 2026/0354129 A1
(43) Pub. Date: Nov. 5, 2026

(54) TRANSISTOR SPACER STRUCTURES AND METHODS OF FORMING

(71) Applicant: Taiwan Semiconductor Manufacturing Co., Ltd., Hsinchu (TW)

(72) Inventors: Cheng-Yu Wei, Taoyuan City (TW); Cheng-I Lin, Hsinchu (TW); Shu-Han Chen, Hsinchu (TW); Chi On Chui, Hsinchu (TW)

(21) Appl. No.: 19/725,549

(22) Filed: Jun. 30, 2026

Related U.S. Application Data
(63) Continuation of application No. 18/796,106, filed on Aug. 6, 2024.

(51) Int. Cl. H10P 76/40; H10D 30/01; H10D 62/10; H10D 64/01; H10D 30/43; H10D 30/67

(52) U.S. Cl. CPC H10P 76/405; H10D 30/014; H10D 62/116; H10D 64/017; H10D 30/43; H10D 30/6735; H10D 30/6757; H10D 62/121

(57) ABSTRACT

A method of forming a semiconductor device that includes forming a hard mask layer on exterior surfaces of a stack of nanostructure layers, in which the hard mask layer including a dielectric base material and a protective oxide surface. A dummy gate is formed on the hard mask layer. A gate sidewall spacer is formed abutting the dummy gate. Source/drain regions are formed. The dummy gate is removed. A first set of the stack of nanostructure layers is removed selectively to a second set of the set of nanostructure layers. The second set of nanostructure layers provides suspended channel regions supported by an inner spacer. A damage path blocking portion of at least the dielectric base material of the hard mask layer is present between the inner spacer and the gate sidewall spacer.

### CROSS-REFERENCE TO RELATED APPLICATIONS

This application is a continuation of U.S. Application No. 18/796,106, filed on Aug. 6, 2024, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6, 7A, 7B, 7C, 8A, 8B, 9A, 9B, 10A, 10B, 10C, 11A, 11B, 12A, 12B, 13A, 13B, 13C, 14A, 14B, 14C, 14D, 14E, 15A, 15B, 15C, 16A, 16B, 17A, 17B, 18A, 18B, 18C, 18D, 19A, 19B, 19C, 20A, 20B, 20C, 20D, 21A, 21B, 21C, 22A, 22B and 22C are cross-sectional views of intermediate stages in the manufacturing of nano-FETs, in accordance with some embodiments.

FIGS. 23A, 23B, 23C and 23D are cross-sectional views of a nano-FET, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure describes methods and structures that employ a hard mask including a dielectric base material with a thin protective oxide surface formed using an oxidation treatment. In some embodiments, the hard mask may be formed as a dummy gate dielectric of a dummy gate stack for a replacement gate process. The mixing ratio of oxygen and noble gas for forming the protective oxide surface can be selected to control the thickness of the protective oxide surface. The thin protective oxide surface protects underlying nanostructures during etch processes for patterning a dummy gate structure. The base dielectric material of the hard mask can block damage pathways to protect epitaxial semiconductor material for the source/drain regions from being etched by etchant used in a replacement gate process for forming a gate all around gate structure and for configuring nanowires for the channel regions of the semiconductor device.

It has been determined that etch stop layers that are formed from deposited oxides when used to protect stacks of semiconductor nanostructures during polysilicon etching in replacement gate process sequences has a number of disadvantages. For example, it is difficult to deposit an oxide layer thickness that is sufficient for protecting the upper surface of semiconductor layer stacks for producing nanostructure channels without producing overhang structures. Additionally, when forming sufficient thicknesses of the oxide on the upper surface of the semiconductor layer stack, a similar thickness of the oxide material is also formed on the sidewalls of that semiconductor layer stack. The thick oxide that is present on the sidewalls of the semiconductor layer stack can be removed during etch process, such as etch processing employed during replacement gate processing, which can result in the formation of damage pathways. The damage pathways can introduce etchant to the epitaxial semiconductor material of the source/drain regions, which can damage the source/drain regions. Additionally, the damage pathways can result in leakage between the contact (MG) to the gate structure and the contact (MD) to the source/drain region.

In some embodiments, the hard mask of the present disclosure including the dielectric base material with the thin protective oxide surface provides a oxide material that serves as an etch stop during polysilicon etching of the dummy gate structures used in the replacement gate process, while the base material of the dielectric material substantially eliminates the formation of the damage pathway. Therefore, in some embodiments, the hard mask described herein including the dielectric base material and protective oxide surface can protect the epitaxial material of the source/drain regions and substantially eliminate the aforementioned leakage between the contact (MG) to the gate structure and the contact (MD) to the source/drain region. In some embodiments, the protective oxide surface has a thickness that is selected to provide protection for the upper semiconductor layers, while not being so thick that if removed could provide a damage pathway through which etchant used in the replacement gate process could reach the epitaxial material of the source/drain regions. For at least this reason, the hard mask described herein including the dielectric base material and the protective oxide surface reduces the width of any potential damage pathway that may form during processes steps for removing oxides.

Embodiments are described below in a particular context, a die comprising nano-FETs. Various embodiments may be applied, however, to dies comprising other types of transistors (e.g., fin field effect transistors (FinFETs), planar transistors, or the like) in lieu of or in combination with the nano-FETs.

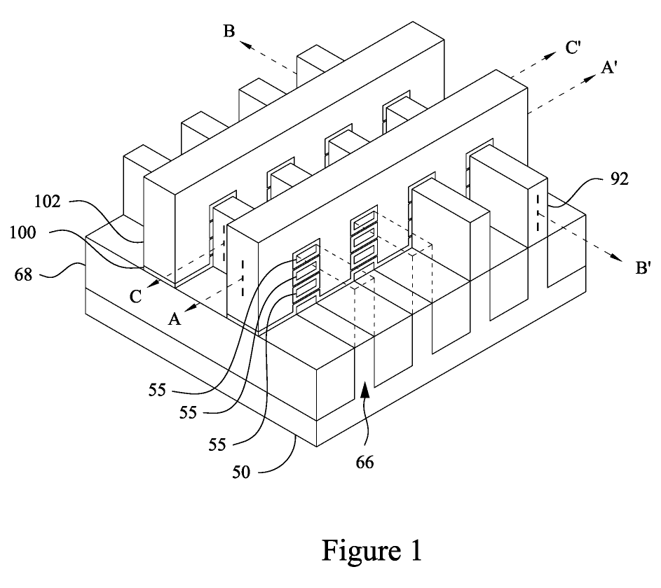

FIG. 1 illustrates an example of nano-FETs (e.g., nanowire FETs, nanosheet FETs (Nano-FETs), or the like) in a three-dimensional view, in accordance with some embodiments. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Isolation regions 68 are disposed between adjacent fins 66, which may protrude above and from between neighboring isolation regions 68. Although the isolation regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring isolation regions 68.

Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

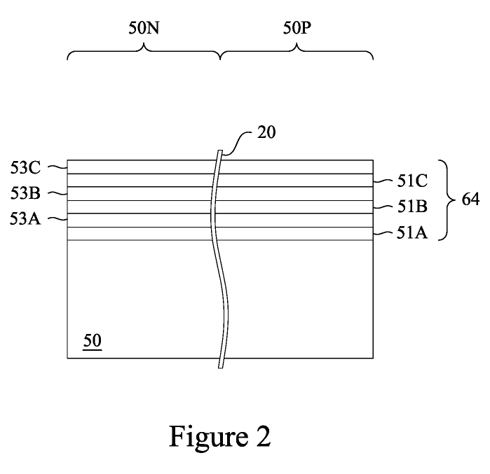

The hard mask layer can be integrated into the three dimensional structure depicted in FIG. 1, as described with reference to FIGS. 2-23c.

FIG. 1 further illustrates reference cross-sections that are used in later figures. Cross-section A-A’ is along a longitudinal axis of a gate electrode 102 and in a direction, for example, perpendicular to the direction of current flow between the epitaxial source/drain regions 92 of a nano-FET. Cross-section B-B’ is perpendicular to cross-section A-A’ and is parallel to a longitudinal axis of a fin 66 of the nano-FET and in a direction of, for example, a current flow between the epitaxial source/drain regions 92 of the nano-FET. Cross-section C-C’ is parallel to cross-section A-A’ and extends through epitaxial source/drain regions of the nano-FETs. Subsequent figures refer to these reference cross-sections for clarity.

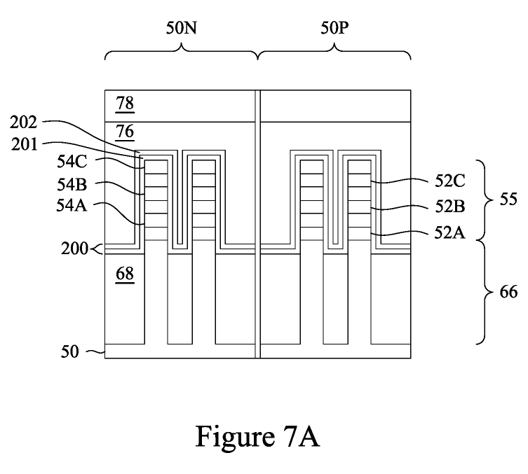

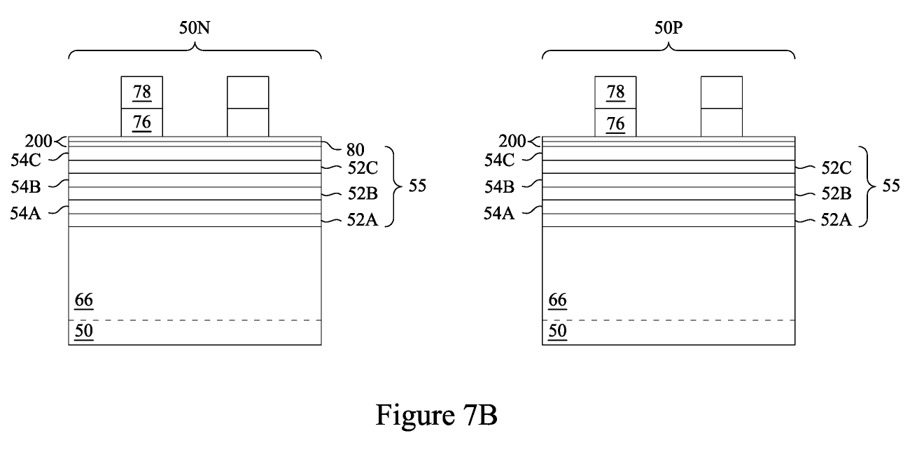

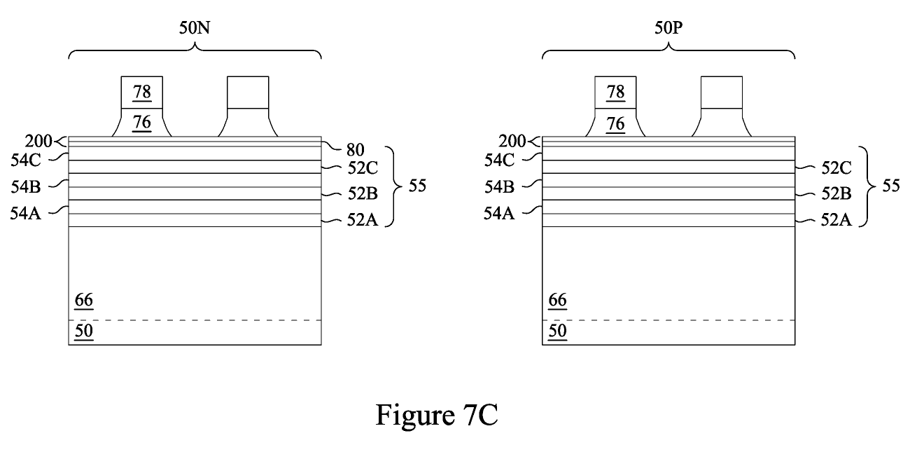

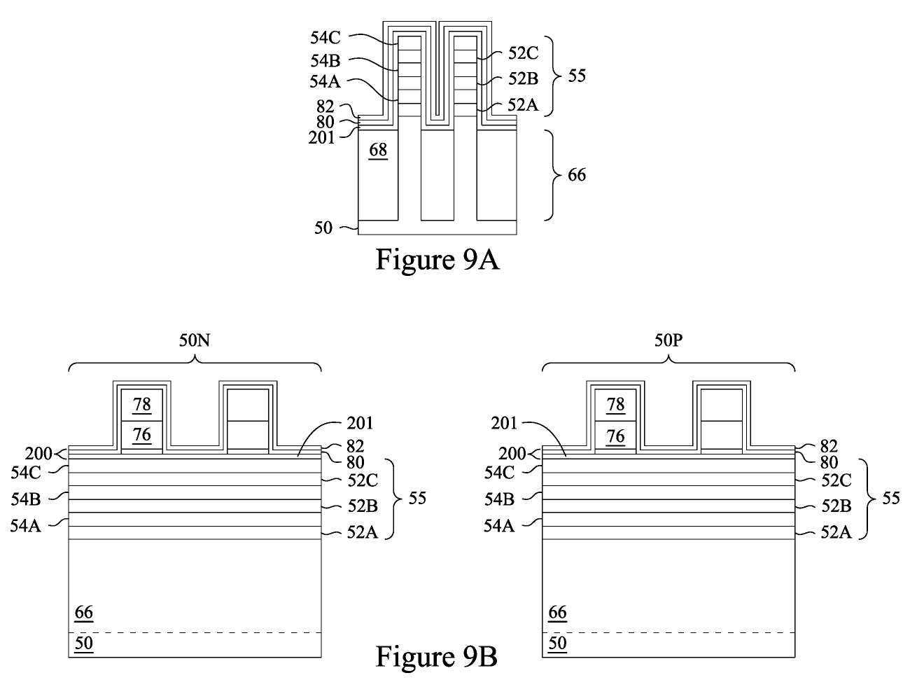

FIGS. 2-23C are cross-sectional views of intermediate stages in the manufacturing of nano-FETs, in accordance with some embodiments. FIGS. 2-6, 7A, 8A, 15A, 16A, 17A, 18A, 19A, 20A, 21A, 22A, and 23A illustrate reference cross-section A-A’ illustrated in FIG. 1. FIGS. 7B, 7C, 8B, 9B, 10B, 10C, 11B, 12B, 13B, 13C, 14B, 14D, 15B, 16B, 17B, 18B, 18C, 18D, 19B, 19C, 20B, 21B, 22B and 23B illustrate reference cross-section B-B’ illustrated in FIG. 1. FIGS. 9A, 10A, 11A, 12A, 13A, 14A, 14C, 15C, 20C, 21C, 22C, and 23C illustrate reference cross-section C-C’ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the second semiconductor layers 53 will be removed and the first semiconductor layers 51 will be patterned to form channel regions of nano-FETs in the p-type region 50P. Also, the first semiconductor layers 51 will be removed and the second semiconductor layers 53 will be patterned to form channel regions of nano-FETs in the n-type region 50N. Nevertheless, in some embodiments the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P.

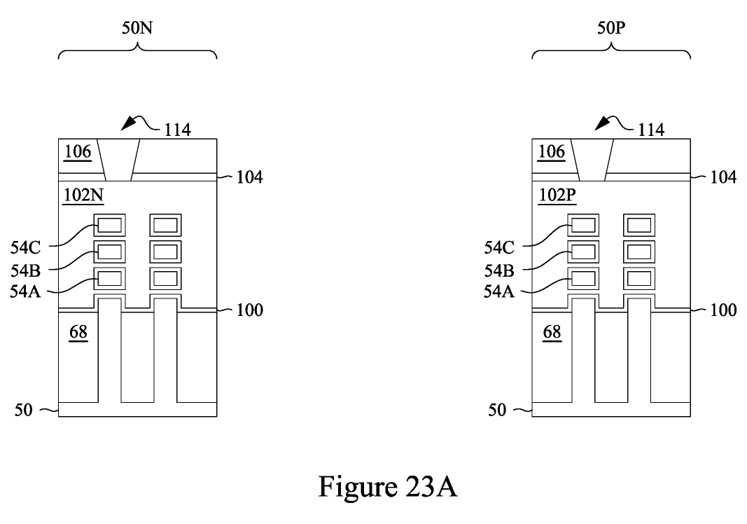

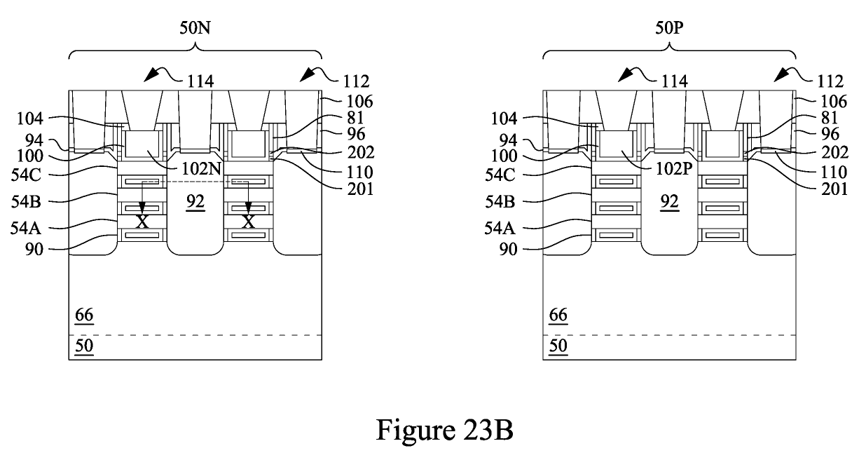

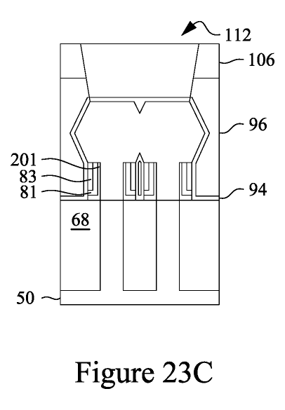

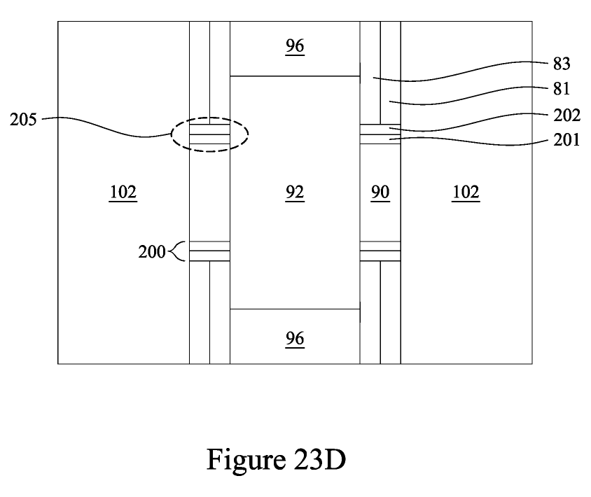

In still other embodiments, the first semiconductor layers 51 may be removed and the second semiconductor layers 53 may be patterned to form channel regions of nano-FETS in both the n-type region 50N and the p-type region 50P. In other embodiments, the second semiconductor layers 53 may be removed and the first semiconductor layers 51 may be patterned to form channel regions of non-FETs in both the n-type region 50N and the p-type region 50P. In such embodiments, the channel regions in both the n-type region 50N and the p-type region 50P may have a same material composition (e.g., silicon, or the another semiconductor material) and be formed simultaneously. FIGS. 23A, 23B, and 23C illustrate a structure resulting from such embodiments where the channel regions in both the p-type region 50P and the n-type region 50N comprise silicon, for example.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material suitable for p-type nano-FETs, such as silicon germanium, or the like, and the second semiconductor layers 53 may be formed of a second semiconductor material suitable for n-type nano-FETs, such as silicon, silicon carbon, or the like. The multi-layer stack 64 is illustrated as having a bottommost semiconductor layer suitable for p-type nano-FETs for illustrative purposes. In some embodiments, multi-layer stack 64 may be formed such that the bottommost layer is a semiconductor layer suitable for n-type nano-FETs.

The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material in the n-type region 50N, thereby allowing the second semiconductor layers 53 to be patterned to form channel regions of n-type nano-FETs. Similarly, the second semiconductor layers 53 of the second semiconductor material may be removed without significantly removing the first semiconductor layers 51 of the first semiconductor material in the p-type region 50P, thereby allowing the first semiconductor layers 51 to be patterned to form channel regions of p-type nano-FETs.

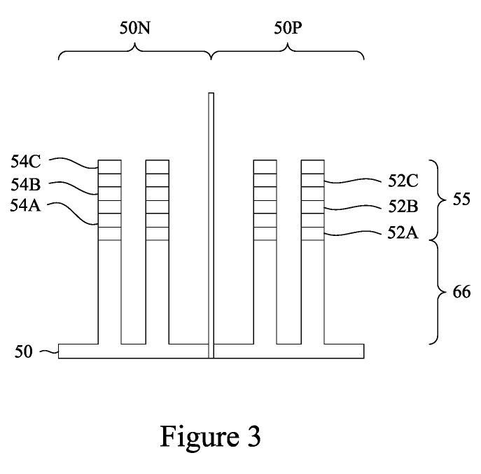

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

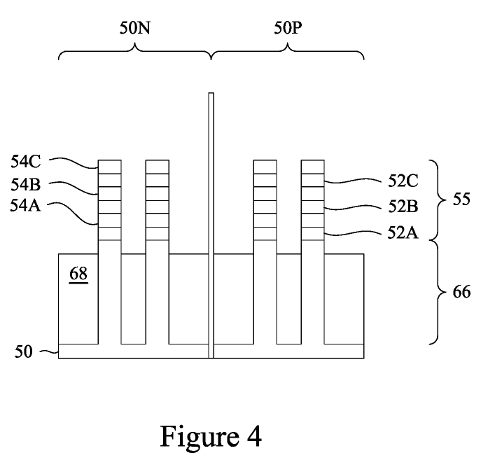

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

The process described above with respect to FIGS. 2-4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting nanostructures 52) and the second semiconductor layers 53 (and resulting nanostructures 54) are illustrated and discussed herein as comprising the same materials in the p-type region 50P and the n-type region 50N for illustrative purposes only. As such, in some embodiments one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In some embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

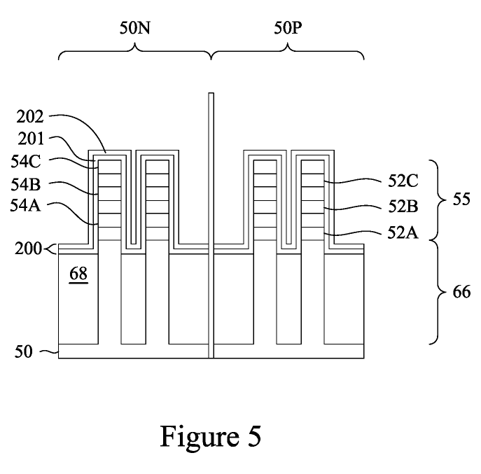

FIG. 5 illustrates one embodiment of forming a hard mask layer 200 including a dielectric base material 201 with a thin protective oxide surface 202. The hard mask is formed on at least the stacks of the nanostructures 55. The thin protective oxide surface 202 can be formed using an oxidation treatment. In some embodiments, the hard mask layer 200 is a conformal layer. The conformal layer for the hard mask layer 200 has a substantially same thickness on the sidewalls of the stacks of nanostructures 55 as the thickness on the upper surfaces of the stacks of nanostructures 55. The material for the dielectric base material 201 may be a dielectric composition that is selected from the group consisting of aluminum oxide (AlOx), silicon carbide (SiC), silicon oxycarbonitride (SiOₓC_{y} N_{1-x-y}), silicon nitride (SiN), silicon boron nitride (SiBN), silicon carbon nitride (SiCN), silicon boron carbon nitride (SiBCN). In some embodiments, the dielectric base material has a dielectric constant at room temperature that is less than the dielectric constant of silicon nitride (SiN), e.g., silicon oxycarbonitride (SiOₓC_{y} N_{1-x-y}). In some embodiments, the base dielectric material 201 has a low-k dielectric constant. A low-k dielectric constant material is a dielectric material having a dielectric constant at room temperature that is less than the dielectric constant of silicon oxide (SiO₂) , e.g., k =4.0. One example of a low-k dielectric constant material that is suitable for the dielectric base material 201 is silicon boron carbon nitride (SiBCN). It is noted that the above compositions are provided for illustrative purposes only, and are not intended to limit the present disclosure. For example, other dielectric material compositions are suitable for the dielectric base material 201, so long as the material composition allows for etch chemistries for etching silicon oxide selectively to the dielectric base material 201.

In some embodiments, the material layer for the dielectric base material 201 may be deposited using atomic layer deposition (ALD). The process conditions for the deposition process may be selected to provide that the material layer for the dielectric base material 201 has a conformal thickness, e.g., the same thickness on the upper surfaces and sidewall surfaces of the stacks of the nanostructures 55. It is noted that atomic layer deposition (ALD) is only one example of a deposition process for forming the dielectric base material 201. For example, the dielectric base material 201 may also be deposited using a chemical vapor deposition (CVD) method, or the like. The thickness of the dielectric base material 201 may range from 20 Å to 45 Å. In one example, in which the composition of the dielectric base material 201 is composed of SiOCN, the thickness of the dielectric base material 201 may range from 20 Å to 45 Å. It is noted that the above examples for the thickness of the dielectric base material 201 have been provided for illustrative purposes only. Other thicknesses may be suitable to the methods and structures described herein, in which the thickness selected is suitable for providing enough material for oxidation of the surface, wherein a remaining portion of the dielectric base material 201 is not oxidized to provide for etch selectivity between the oxidized and non-oxidized portions.

In some embodiments, following the deposition of the dielectric base material 201, an oxidation process is applied to the upper surface of the dielectric base material 201 to convert the upper surface of the dielectric base material 201 into a thin protective oxide surface 202. In some embodiments, in which the dielectric base material 201 is a silicon (Si) containing composition, oxygen from the oxidation process reacts with silicon at the surface of the dielectric base material 201 to provide silicon oxide (SiO₂). It is noted that silicon oxide is only one example for the composition for the thin protective oxide surface 202. In some embodiments, in addition to silicon and oxygen, the thin protective oxide surface 202 may also include elements of carbon, hydrogen and nitrogen.

In some embodiments, the thin protective oxide surface 202 has a conformal thickness and is a continuous layer that is formed onto the exterior surface of the dielectric base material 201. Forming the thin protective oxide surface 202 may consume a portion of the dielectric base material 201. The incorporation of oxygen from the oxidation process for forming the thin protective oxide surface 202 may gradually extend into a depth of the dielectric base material 201. More particularly, in some embodiments, the oxygen concentration may having a high concentration when closer to the upper surface of the thin protective oxide surface 202 and then gradually decreases towards the interface between the thin protective oxide surface 202 and the dielectric base material 201. In some embodiments, a portion of the dielectric base material 201 may be completely free of oxygen from the oxidation process. The protective oxide surface has a thickness that is selected to provide sufficient protection for the upper semiconductor layers, while not being so thick that if removed could provide an unduly large damage pathway through which etchant used in the replacement gate process could reach the epitaxial material of the source/drain regions. For at least this reason, the hard mask including the dielectric base material and the protective oxide surface reduces the width of any potential damage pathway that may form during processes steps for removing oxides. In some embodiments, the thin protective oxide surface 202 has a thickness that ranges from 10 Å to 35 Å. In some embodiments, a remaining portion of the dielectric base material 201 after the oxidation process that forms the thin protective oxide surface 202 may have a thickness that ranges from 10 Å to 35 Å. In some embodiments, the ratio of the thickness of the protective oxide surface 202 to the thickness of the dielectric base material 201 ranges from 30% to 70%.

In some embodiments, the oxidation process for forming the thin protective oxide surface 202 is a thermal oxidation process. In some examples, thermal oxidation uses an exposure to oxygen, e.g., oxygen containing gas, and high temperatures to grow silicon oxide layers directly on a silicon containing surface, e.g., the exterior surfaces of the dielectric base material 201. For example, the temperature of the thermal oxidation process may range from 800° C. to 1200° C. In some examples, as the surface of the dielectric base material 201 reacts with oxygen, silicon from the dielectric base material diffuses to the surface while the oxygen species diffuse inward. This chemical reaction results in the conversion of silicon to silicon oxide at the silicon-oxygen interface.

In some embodiments, by controlling temperature, gas delivery, and exposure time, the oxide thickness for the thin protective oxide surface 202 can be controlled to thicknesses ranging from a 10 Å up to 35 Å.

In some embodiments, to control the oxide thickness for the protective oxide surface 202, the oxygen gas delivery during the thermal oxidation process may be adjusted. For example, oxygen gas delivery includes oxygen (O₂) gas and a noble gas (e.g., He, Ar, Ne, Xe, Kr, or the like). In some embodiments, the noble gas is flowed concurrently with the oxygen (O₂) gas. In some embodiments, the gas mixture of the oxygen gas and noble gas, i.e., O₂/noble gas mixture ratio, can be adjusted to control the thickness of the thin protective oxide surface 202. For example, the gas mixture of the oxygen gas and noble gas, i.e., O₂/noble gas mixture ratio, can be adjusted to range from 20% to 80%. Increased oxidation can be provided by increasing the percentage of noble gas to oxygen, which can help ionization or dissociation. In some embodiments, a higher O²% in the O₂/noble gas mixture ratio can produce thinner oxide thicknesses due to less assistance (ionization or dissociation) of the noble gas. The thickness of the thin protective oxide surface 202 may also be adjusted by adjusting the pressure and power of the thermal oxidation process. In some embodiments, higher power can lead to more energetic plasma reaction, which can produce a thicker oxide thickness. In some embodiments, higher process pressure can create lower ion energy and density, which can lead to thinner oxide thickness.

It is noted that the above oxidation process is only one example of oxidation processes that can be suitable for use with the methods and structures of the present disclosure. Other oxidation processes may also be suitable for forming the protective oxide surface 202, such as rapid thermal oxidation process, plasma oxidation and/or steam oxidation.

In FIG. 5, the hard mask layer 200 including the dielectric base material 201 with thin protective oxide surface 202 is present in each of the n-type region 50N and the p-type region 50P. For each of the n-type region 50N and the p-type region 50P, a continuous hard mask layer 200 is present on the sidewalls and upper surfaces for each of the stacks of nanostructures 55. In some examples, the hard mask layer can also be present on the upper surfaces of the STI regions 68 between adjacent stacks of the nanostructures 55.

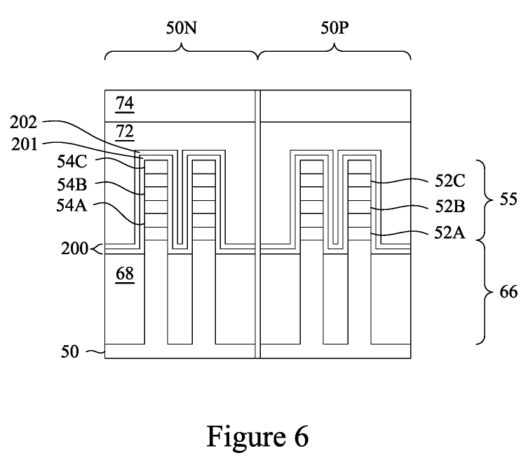

In FIG. 6, a dummy gate layer 72 is formed over the hard mask layer 200, and a mask layer 74 is formed over the dummy gate layer 72. The dummy gate layer 72 may be deposited over the hard mask layer 200 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In some embodiments, the mask layer 74 may have a multilayer structure. In this example, a single mask layer 74 are formed across the n-type region 50N and the p-type region 50P.

FIGS. 7A-21C illustrate various additional steps in the manufacturing of embodiment devices. In FIGS. 7A and 7B, the mask layer 74 (see FIG. 6) may be patterned using acceptable photolithography and etching techniques to form masks 78. The pattern of the masks 78 then may be transferred to the dummy gate layer 72 to form dummy gates 76. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

The etch process for patterning the dummy gates 76 may be an anisotropic etch, such as reactive ion etching (RIE). The dummy gates 76 may be composed of polysilicon. During the etch process for patterning the dummy gate 76, the etch process may be selective to the hard mask layer 200. For example, the etch process for etching the dummy gate 76 may be selected to the thin protective oxide surface 202 of the hard mask layer 200. In one example, the etch chemistry can remove the polycrystalline-silicon (polysilicon) of the dummy gate 76 selective to the thermal oxide material, e.g., silicon oxide, of the thin protective oxide surface 202. Although FIG. 7B illustrates the sidewalls of the dummy gates 76 as being substantially straight, the etching process may form the dummy gates 76 to have curved sidewalls, particularly around the bases of the dummy gates 76 as illustrated by FIG. 7C.

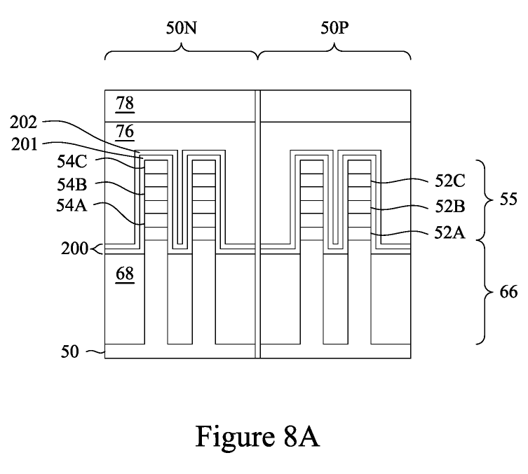

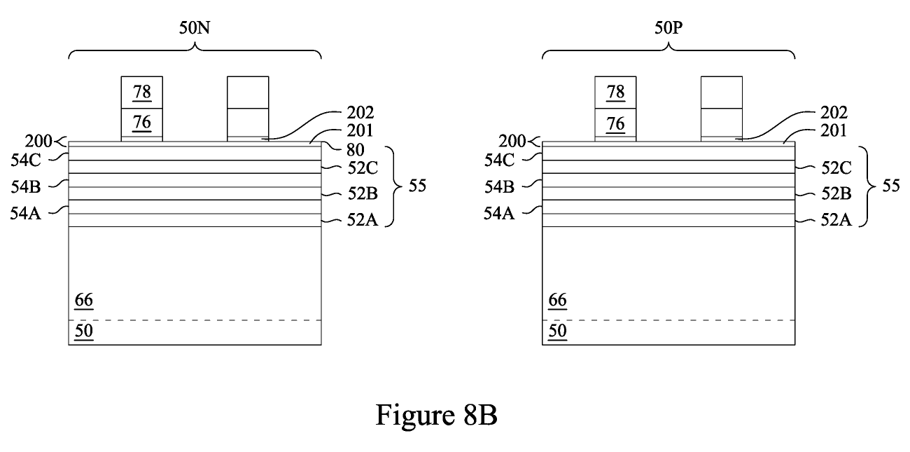

In some embodiments, the thin protective oxide surface 202 has etch resistance to the etch chemistries for removing the dummy gate 76. For example, the oxide containing surface, e.g., silicon oxide material surface, has etch resistance to etch chemistries for removing silicon containing semiconductor materials, such as polycrystalline-silicon (polysilicon). In some embodiments, the hard mask layer 200 is present over and protects the upper semiconductor material layers. For example, the protective oxide surface 202 protects the silicon (Si) or silicon carbide (SiC) material of the second nanostructures 54C during the etch processes for patterning the dummy gate 76, e.g., polysilicon material of the dummy gate 76. As such, the relatively thin protective oxide surface protects the upper semiconductor layers from being etched by the etch process that patterns the dummy gate 76, while having a thickness that does not result in a large opening that can provide a damage pathway to the epitaxial material of the source and drain regions when exposed to etch processes that remove oxide materials during the replacement gate process. In FIGS. 8A and 8B, an oxide clean step is performed. In some embodiments, the oxide clean step removes the exposed portions of the thin protective oxide surface 202 of the hard mask layer 200 without removing the underlying dielectric base material 201. The exposed portion of the thin protective oxide surface 202 that is removed by the oxide clean step is the portion of the thin protective oxide surface 202 of the hard mask layer 200 that is not covered by the dummy gate 76. In some embodiments, the portion of the thin protective oxide surface 202 that is present underlying the dummy gate 76 remains following the oxide clean step.

The oxide clean step is a process that removes the composition of the thin protective oxide surface 202 without removing the dielectric base material 201. For example, the oxide clean step may be an etch process, such as a wet etch process or dry etch process. The wet etch process may be isotropic. The dry etch process can be anisotropic. The chemistry for the etch process may remove the thin protective oxide surface 202 selectively to the dielectric base material 201. For example, when the thin protective oxide surface 202 is composed of silicon oxide (SiO₂), the oxide clean step may include a wet etch process with a Buffered Oxide Etch (BOE) solution, or a dry plasma etch with etchant gases such as CF₄, SF₆, NF₃, and the like. One example of a BOE solution can include a mixture of 40% solution of NH₄F in water and 49% solution of HF in water. In some examples, residual oxide may be removed using a wet etch process with 0.7% HF solution in water for a duration about 60 seconds.

In FIGS. 9A and 9B, a first spacer layer 80 and a second spacer layer 82 are formed over the structures illustrated in FIGS. 8A and 8B, respectively. The first spacer layer 80 and the second spacer layer 82 will be subsequently patterned to act as spacers for forming self-aligned source/drain regions. In FIGS. 9A and 9B, the first spacer layer 80 is formed on top surfaces of the STI regions 68; top surfaces and sidewalls of the fins 66, the nanostructures 55, and the masks 78; and sidewalls of the dummy gates 76. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 1x10¹⁵ atoms/cm³ to about 1x10¹⁹ atoms/cm³. An anneal may be used to repair implant damage and to activate the implanted impurities.

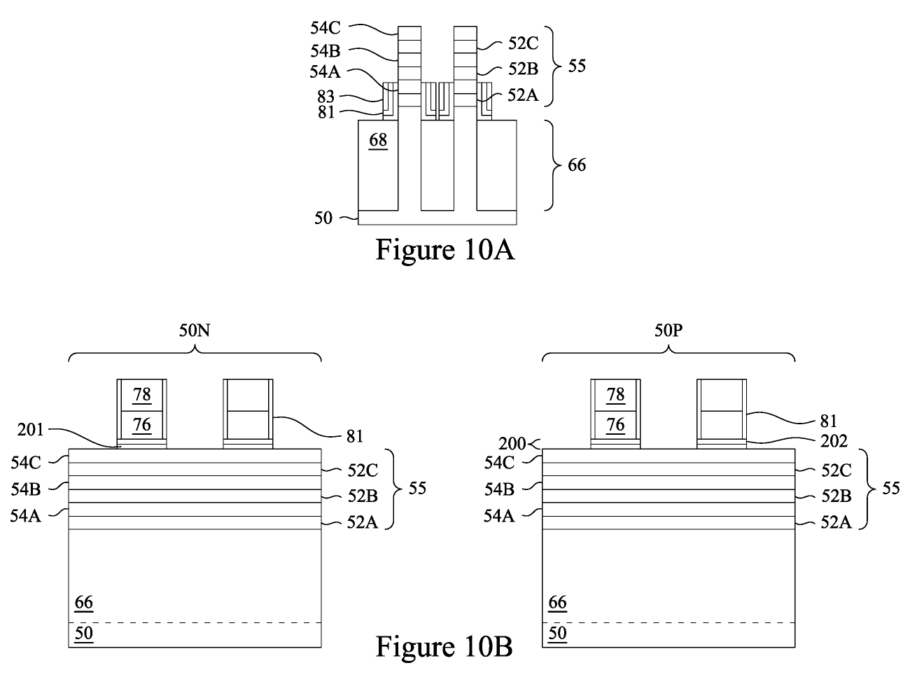

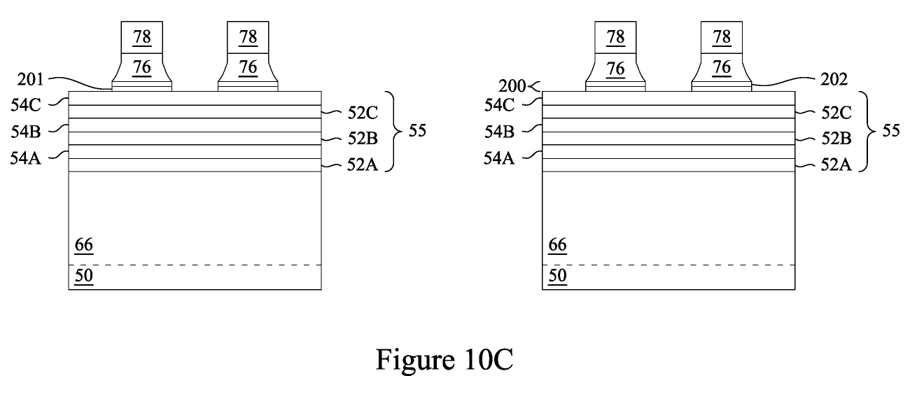

In FIGS. 10A-10C, the first spacer layer 80 and the second spacer layer 82 are etched to form first spacers 81 and second spacers 83. In some embodiments, following the etch sequence that etches the first spacer layer 80 and the second spacer layer 82 to provide the first and second spacers 81, 83, the exposed portions of the dielectric base material 201 of the hard mask layer 200 may also be etched. For example, after forming the first and second spacers 81, 83, the exposed portions of the dielectric base material 201 of the hard mask layer 200 may be etched selectively to the second nanostructures 54C.

As will be discussed in greater detail below, the first spacers 81 and the second spacers 83 act to self-align subsequently formed source drain regions, as well as to protect sidewalls of the fins 66 and/or nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 8A. Thereafter, the second spacers 83 acts as a mask while etching exposed portions of the first spacer layer 80, thereby forming first spacers 81 as illustrated in FIG. 8A.

Following formation of the first and second spacers 81, 83, the exposed portions of the dielectric base material 201 of the hard mask layer 200 may be etched using a suitable etching process, such as an isotropic etching process (e.g., a wet etching process), an anisotropic etching process (e.g., a dry etching process), or the like. Thereafter, the first and second spacers 81, 83 act as a mask while etching exposed portions of the dielectric base material 201 of the hard mask layer 200. The etch process for removing the exposed portions of the dielectric base material 201 of the hard mask layer 200 may be etched selectively to the second nanostructures 54C. In some embodiments, following the etch process for removing the exposed portions of the hard mask layer 200, remaining portions of the hard mask layer 200 are present under the base surfaces of the first and second spacers 81, 83, and between the first and second spacers 81, 32 and the sidewalls for a portion of the stacks of first and second nanostructures 52, 54. In some embodiments, the remaining portions of the hard mask layer 200 that are under the base surfaces of the first and second spacers 81, 83, and between the first and second spacers 81, 83 and the sidewalls of the stacks of first and second nanostructures 52, 54, can include a remaining portion of the dielectric base material 201 and a remaining portion of the thin protective oxide surface 202.

As illustrated in FIG. 10A, the first spacers 81 and the second spacers 83 are disposed on the remaining portions of the hard mask layer 200 on the sidewalls of the fins 66 and/or nanostructures 55. As illustrated in FIG. 10B, in some embodiments, the second spacer layer may be removed from over the first spacer layer 80 adjacent the masks 78, and the dummy gates 76, and the first spacers 81 are disposed on sidewalls of the masks 78, and the dummy gates 76. In other embodiments, a portion of the second spacer layer 82 may remain over the first spacer layer 80 adjacent the masks 78, and the dummy gates 76 to provide the second spacer 83. FIG. 10C illustrates the sidewalls of the dummy gates 76 being curved, particularly around the bases of the dummy gates 76. FIG. 10C illustrates etching the first spacer layer 80 and the second spacer layer 82 to form first spacers 81 and second spacers 83 on the curved sidewalls of the dummy gates 76.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

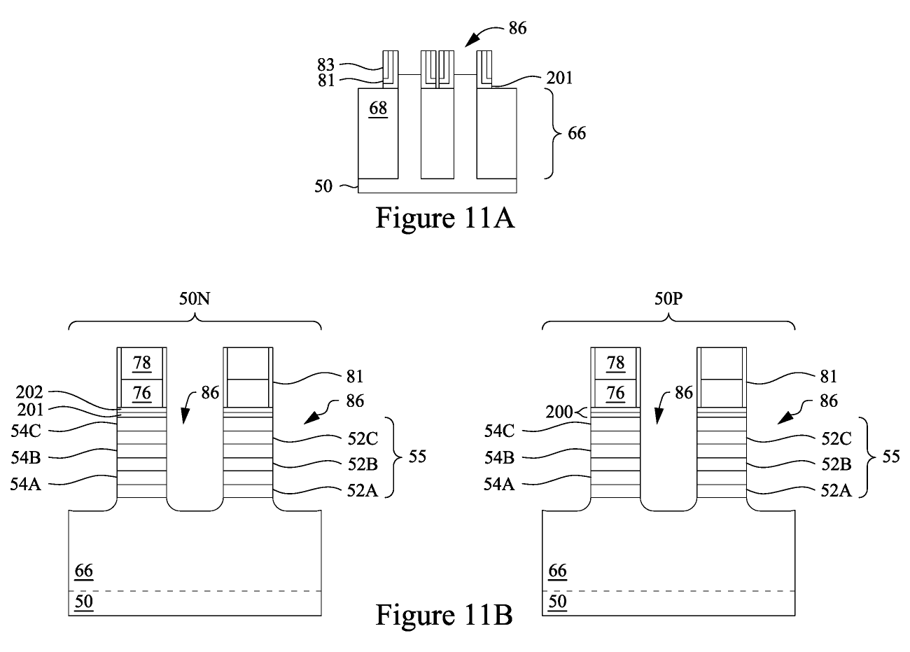

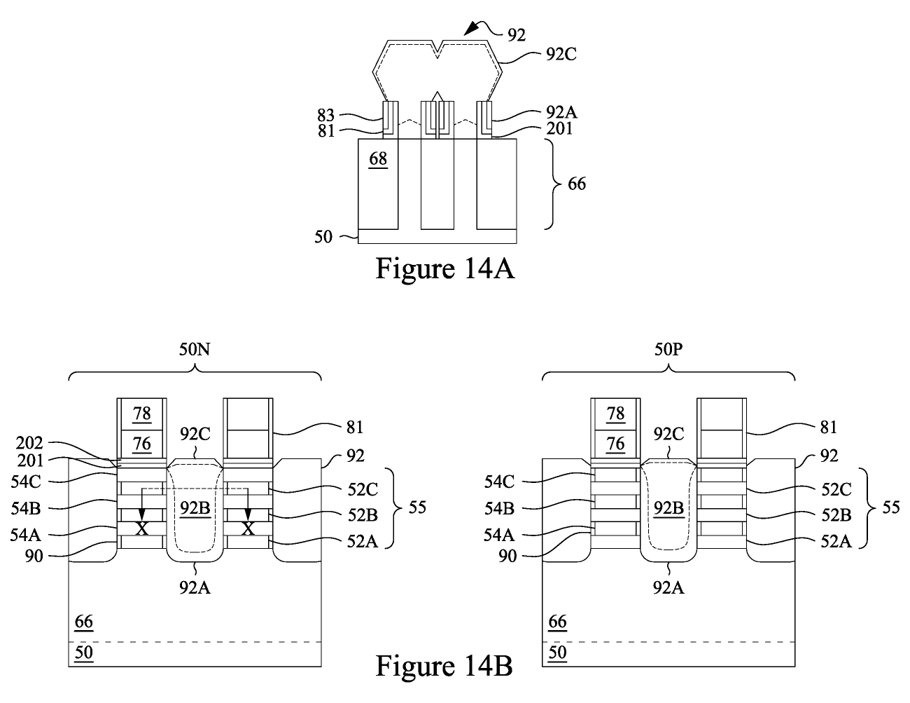

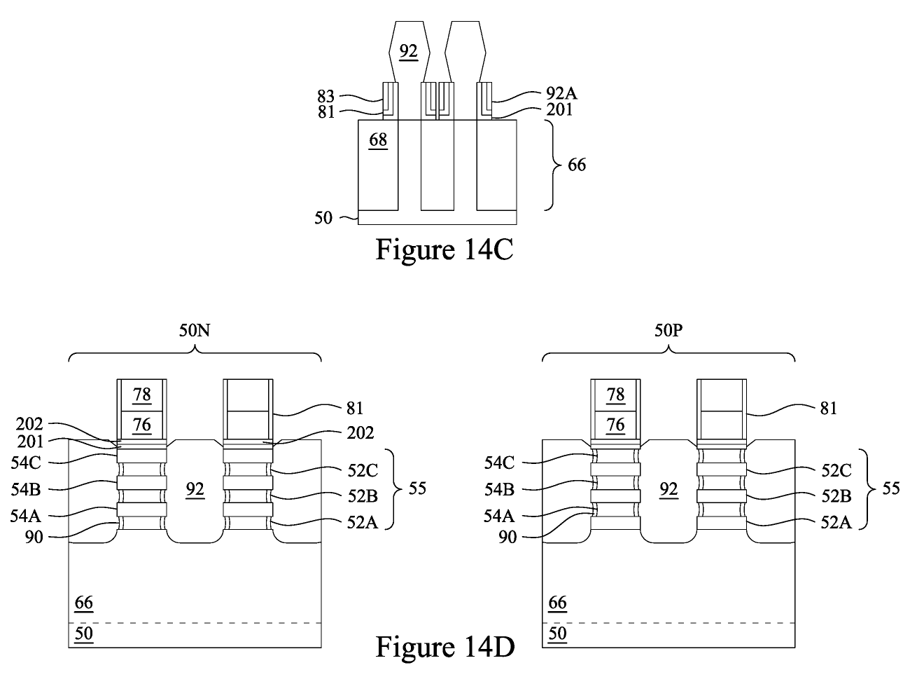

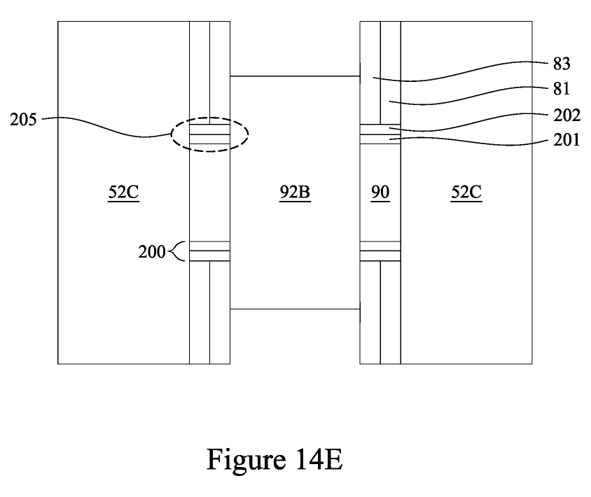

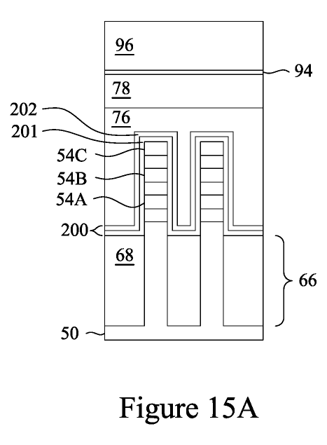

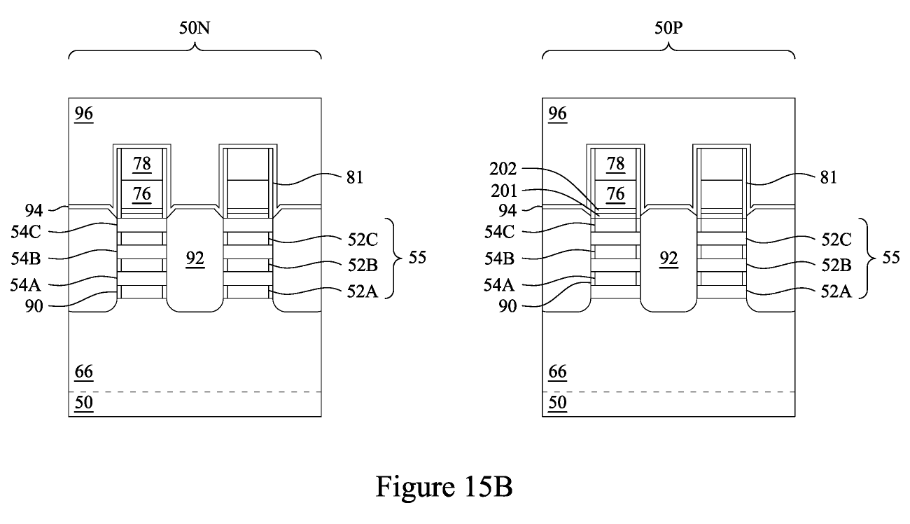

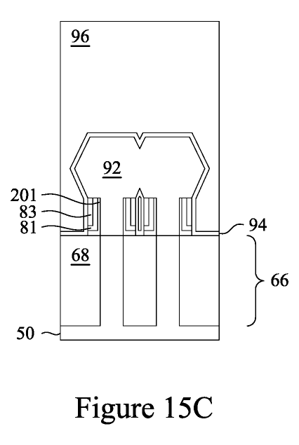

In FIGS. 11A and 11B, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 11A, top surfaces of the STI regions 68 may be level with bottom surfaces of the first recesses 86. In various embodiments, the fins 66 may be etched such that bottom surfaces of the first recesses 86 are disposed below the top surfaces of the STI regions 68; or the like. The first recesses 86 may be formed by etching the fins 66, the nanostructures 55, and the substrate 50 using anisotropic etching processes, such as reactive ion etching (RIE), neutral beam etching (NBE), or the like. The first spacers 81, the second spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth. It is noted that a portion of the hard mask layer 200 (including remaining portions of the dielectric base material 201 and the thin protective oxide surface 202) remains between the sidewalls of the stacks of nanostructures and the spacer structure provided by the first and second spacers 81, 83 (see e.g., FIGS. 14E and 15C).

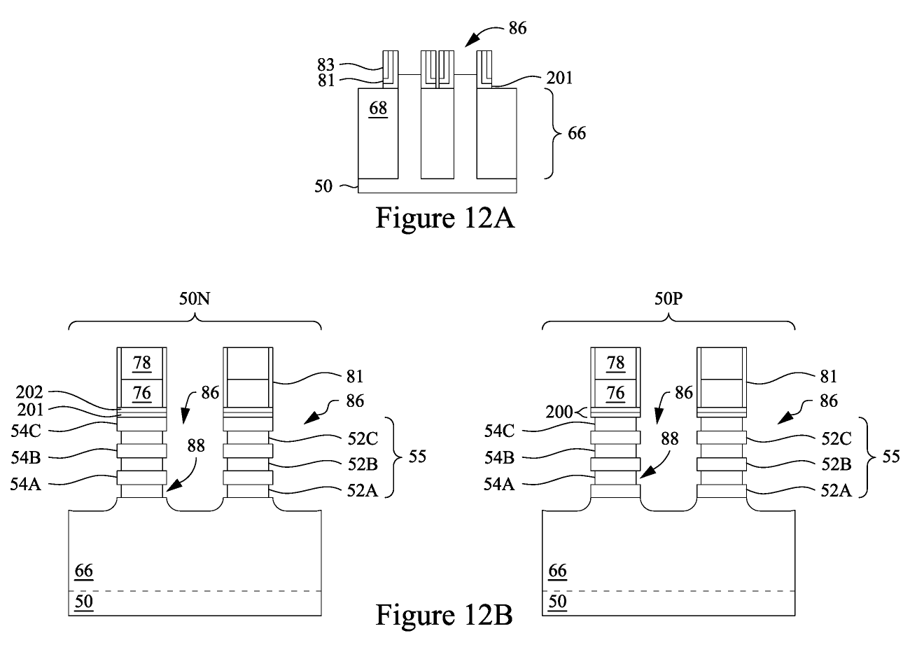

In FIGS. 12A and 12B, portions of sidewalls of the layers of the multi-layer stack 64 formed of the first semiconductor materials (e.g., the first nanostructures 52) exposed by the first recesses 86 are etched to form sidewall recesses 88 in the n-type region 50N, and portions of sidewalls of the layers of the multi-layer stack 56 formed of the second semiconductor materials (e.g., the second nanostructures 54) exposed by the first recesses 86 are etched to form sidewall recesses 88 in the p-type region 50P. Although sidewalls of the first nanostructures 52 and the second nanostructures 54 in sidewall recesses 88 are illustrated as being straight in FIG. 12B, the sidewalls may be concave or convex. The sidewalls may be etched using isotropic etching processes, such as wet etching or the like. The p-type region 50P may be protected using a mask (not shown) while etchants selective to the first semiconductor materials are used to etch the first nanostructures 52 such that the second nanostructures 54 and the substrate 50 remain relatively unetched as compared to the first nanostructures 52 in the n-type region 50N. Similarly, the n-type region 50N may be protected using a mask (not shown) while etchants selective to the second semiconductor materials are used to etch the second nanostructures 54 such that the first nanostructures 52 and the substrate 50 remain relatively unetched as compared to the second nanostructures 54 in the p-type region 50P. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to etch sidewalls of the first nanostructures 52 in the n-type region 50N, and a wet or dry etch process with hydrogen fluoride, another fluorine-based etchant, or the like may be used to etch sidewalls of the second nanostructures 54 in the p-type region 50P.

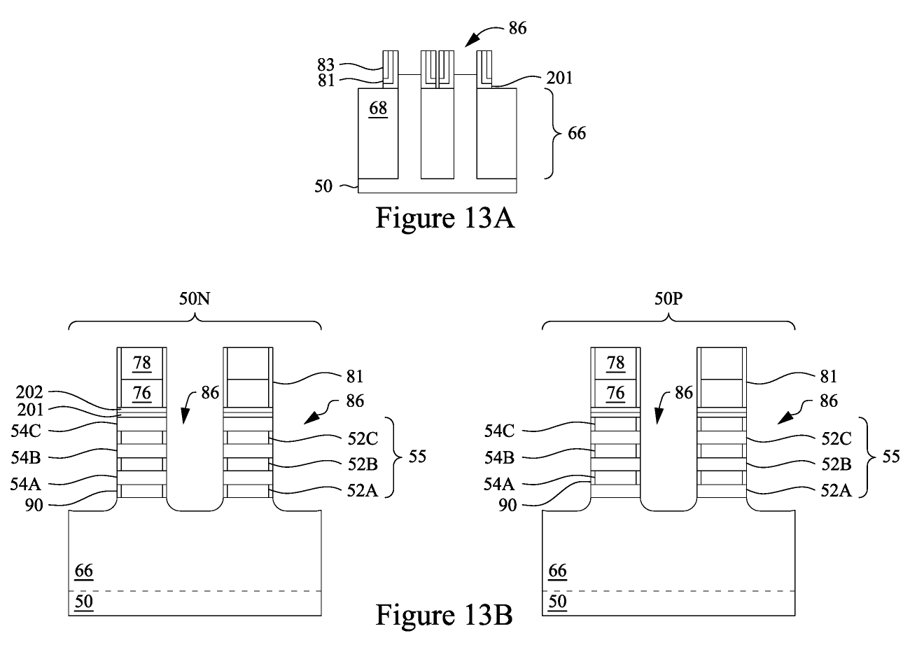

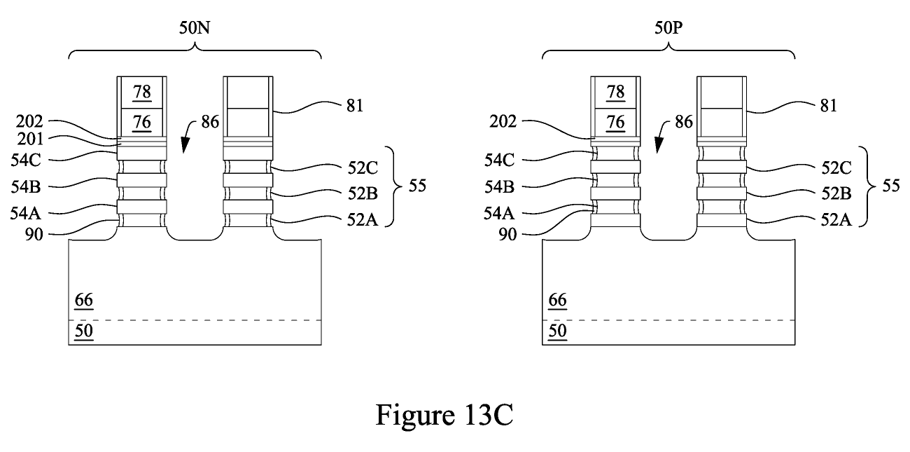

In FIGS. 13A-13C, first inner spacers 90 are formed in the sidewall recess 88. The first inner spacers 90 may be formed by depositing an inner spacer layer (not separately illustrated) over the structures illustrated in FIGS. 12A and 12B. The first inner spacers 90 act as isolation features between subsequently formed source/drain regions and a gate structure. As will be discussed in greater detail below, source/drain regions will be formed in the recesses 86, while the first nanostructures 52 in the n-type region 50N and the second nanostructures 54 in the p-type region 50P will be replaced with corresponding gate structures. Additionally, a remaining portion (not shown in FIGS. 12A and 12B) of the hard mask layer 200 will be present between and in direct contact with the first inner spacers 90, and the first and second spacers 81, 83.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials may be utilized. The inner spacer layer may then be anisotropically etched to form the first inner spacers 90. Although outer sidewalls of the first inner spacers 90 are illustrated as being flush with sidewalls of the second nanostructures 54 in the n-type region 50N and flush with the sidewalls of the first nanostructures 52 in the p-type region 50P, the outer sidewalls of the first inner spacers 90 may extend beyond or be recessed from sidewalls of the second nanostructures 54 and/or the first nanostructures 52, respectively.

Moreover, although the outer sidewalls of the first inner spacers 90 are illustrated as being straight in FIG. 13B, the outer sidewalls of the first inner spacers 90 may be concave or convex. As an example, FIG. 13C illustrates an embodiment in which sidewalls of the first nanostructures 52 are concave, outer sidewalls of the first inner spacers 90 are concave, and the first inner spacers 90 are recessed from sidewalls of the second nanostructures 54 in the n-type region 50N. Also illustrated are embodiments in which sidewalls of the second nanostructures 54 are concave, outer sidewalls of the first inner spacers 90 are concave, and the first inner spacers 90 are recessed from sidewalls of the first nanostructures 52 in the p-type region 50P. The inner spacer layer may be etched by an anisotropic etching process, such as RIE, NBE, or the like. The first inner spacers 90 may be used to prevent damage to subsequently formed source/drain regions (such as the epitaxial source/drain regions 92, discussed below with respect to FIGS. 14A-14C) by subsequent etching processes, such as etching processes used to form gate structures.

Further, the remaining portion of the hard mask layer 200 (discussed below with respect to FIGS. 14A-14C and 14E) that is present between and in direct contact with the first inner spacers 90 and the first and second spacers 81, 83 will reduce the possibility of leakage pathways, i.e., openings, at the interface between the first inner spacers 90 and the first and second spacers 81, 83. The existence of damage pathways, i.e., openings, at the interface between the first inner spacers 90 and the first and second spacers 81, 83, could provide a pathway by which etchants used for removing the sacrificial structures for the replacement gate loop (RPG) and the formation of nanostructures can reach the epitaxial material of the source/drain regions, which can damage the epitaxial material. The hard mask layer 200 described herein can substantially reduce the risk of epitaxial material damage in the source/drain regions that can occur through the aforementioned damage pathways, because the composition of the dielectric base material 201 for the hard mask layer 200 is resistant to being removed by the etch chemistries used in the replacement gate loop (RPG) and in the formation of nanostructures.

In FIGS. 14A-14C, epitaxial source/drain regions 92 are formed in the first recesses 86. In some embodiments, the source/drain regions 92 may exert stress on the second nanostructures 54 in the n-type region 50N and on the first nanostructures 52 in the p-type region 50P, thereby improving performance. As illustrated in FIG. 12B, the epitaxial source/drain regions 92 are formed in the first recesses 86 such that each dummy gate 76 is disposed between respective neighboring pairs of the epitaxial source/drain regions 92. In some embodiments, the first spacers 81 are used to separate the epitaxial source/drain regions 92 from the dummy gates 76 and the first inner spacers 90 are used to separate the epitaxial source/drain regions 92 from the nanostructures 55 by an appropriate lateral distance so that the epitaxial source/drain regions 92 to not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the first nanostructures 52 are silicon germanium, the epitaxial source/drain regions 92 may comprise materials exerting a compressive strain on the first nanostructures 52, such as silicon-germanium, boron doped silicon-germanium, germanium, germanium tin, or the like. The epitaxial source/drain regions 92 may also have surfaces raised from respective surfaces of the multi-layer stack 56 and may have facets.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1x10¹⁹ atoms/cm³ and about 1x10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 14A. In other embodiments, adjacent epitaxial source/drain regions 92 remain separated after the epitaxy process is completed as illustrated by FIG. 14C. In the embodiments illustrated in FIGS. 14A and 14C, the first spacers 81 may be formed to a top surface of the STI regions 68 thereby blocking the epitaxial growth. In some other embodiments, the first spacers 81 may cover portions of the sidewalls of the nanostructures 55 further blocking the epitaxial growth. In some embodiments, a remaining portion of the hard mask layer 200 may be present between the first spacer 81 and the epitaxial material for the source and drain region 92. In some other embodiments, the spacer etch used to form the first spacers 81 may be adjusted to remove the spacer material to allow the epitaxially grown region to extend to the surface of the STI region 58.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

FIG. 14D illustrates an embodiment in which sidewalls of the first nanostructures 52 in the n-type region 50N and sidewalls of the second nanostructures 54 in the p-type region 50P are concave, outer sidewalls of the first inner spacers 90 are concave, and the first inner spacers 90 are recessed from sidewalls of the second nanostructures 54 and the first nanostructures 52, respectively. As illustrated in FIG. 14D, the epitaxial source/drain regions 92 may be formed in contact with the first inner spacers 90 and may extend past sidewalls of the second nanostructures 54 in the n-type region 50N and past sidewalls of the first nanostructures 52 in the p-type region 50P.

FIG. 14E is a top down view along the cross section identified by section line X-X in FIG. 14B. FIG. 14E illustrates the location of a damage pathway blocking portion 205 of the hard mask layer 200 present between and in direct contact with the first inner spacers 90 and the first and second spacers 81, 83. The damage pathway block portion 205 of the hard mask layer 200 substantially reduces the risk of epitaxial material damage in the source/drain regions 92B, because the composition of the dielectric base material 201 for the hard mask layer 200 is resistant to being removed by the etch chemistries used in the replacement gate loop (RPG) and in the formation of nanowires. Therefore, the damage pathway block portion 205 of the hard mask layer 200 will reduce the possibility of pathways, i.e., openings, at the interface between the first inner spacers 90 and the first and second spacers 81, 83.

In some embodiments, the damage pathway block portion 205 of the hard mask layer 200 can reduce the size, e.g., width, of damage pathways. Prior to the methods and structures of the present disclosure, damage pathways, i.e., openings, could occur at the interface of the inner spacers 90 and first and second spacers 81, 83. Prior to the use of the hard mask layer 200 that is described herein, the existence of damage pathways, i.e., openings, at the interface between the first inner spacers 90 and the first and second spacers 81, 83 could provide a pathway by which etchants used for removing the sacrificial structures for the replacement gate loop (RPG) and the formation of nanowires can reach the epitaxial material of the source/drain regions 92, which can damage the epitaxial material. The damage pathway block portion 205 of the hard mask layer 200 can protect the epitaxial semiconductor material of the source/drain regions, because the etch resistant dielectric base material 201 remains at the interface between the first inner spacers 90 and the first and second spacers 81, 83 throughout the replacement gate loop and the processing of the nanowires. The presence of the damage pathway block portion 205 of the hard mask layer 200 substantially blocks etchant from reaching the epitaxial material of the source/drain regions 92.

In some embodiments, the protective oxide surface 202 portion of the damage pathway block portion 205 may be removed. However, the thickness of the protective oxide surface 202 is so thin, that the removal of the protective oxide surface 202 in combination with the presence of the dielectric base material 201 provide that the opening for a damage pathway be limited in width to only 45 Å or less.

In FIGS. 15A-15C, a first interlayer dielectric (ILD) 96 is deposited over the structure illustrated in FIGS. 8A, 14B, and 14A (the processes of FIGS. 9A-14E do not alter the cross-section illustrated in FIG. 8A), respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the first spacers 81. The CESL 94 may comprise a dielectric material, such as, silicon nitride, silicon oxide, silicon oxynitride, or the like, having a different etch rate than the material of the overlying first ILD 96.

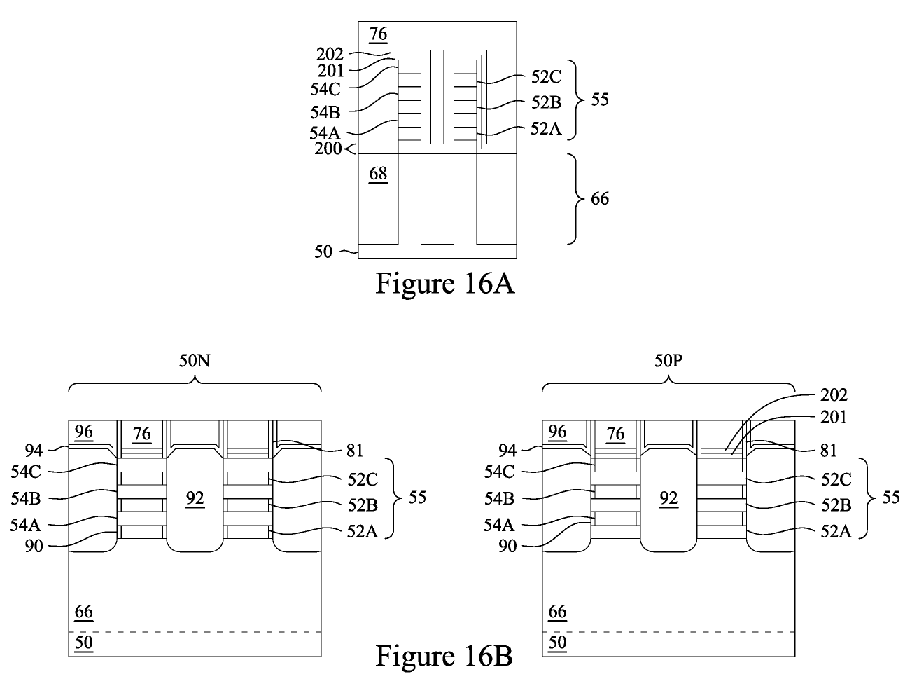

In FIGS. 16A-16C, a planarization process, such as a CMP, may be performed to level the top surface of the first ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 are level within process variations. Accordingly, the top surfaces of the dummy gates 72 are exposed through the first ILD 96. In some embodiments, the masks 78 may remain, in which case the planarization process levels the top surface of the first ILD 96 with top surface of the masks 78 and the first spacers 81.

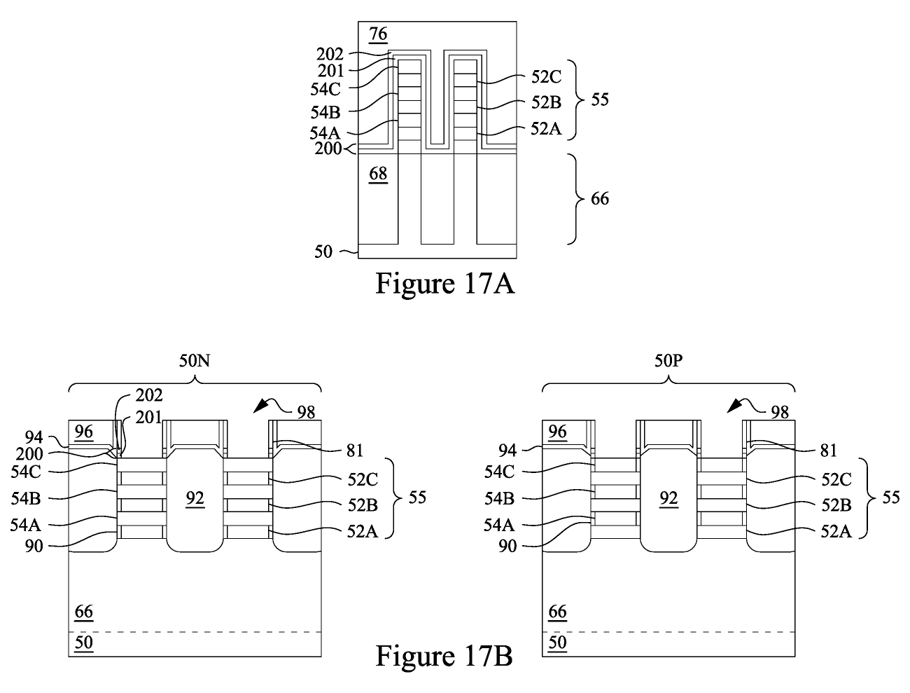

In FIGS. 17A and 17B, the dummy gates 76, and the masks 78 if present, are removed in one or more etching steps, so that second recesses 98 are formed. Portions of the dummy dielectric layers 60 in the second recesses 98 are also be removed. In some embodiments, the dummy gates 76 and the dummy dielectric layers 60 are removed by an anisotropic dry etch process. For example, the etching process may include a dry etch process using reaction gas(es) that selectively etch the dummy gates 76 at a faster rate than the first ILD 96 or the first spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy dielectric layers 60 may be used as etch stop layers when the dummy gates 76 are etched. The dummy dielectric layers 60 may then be removed after the removal of the dummy gates 76.

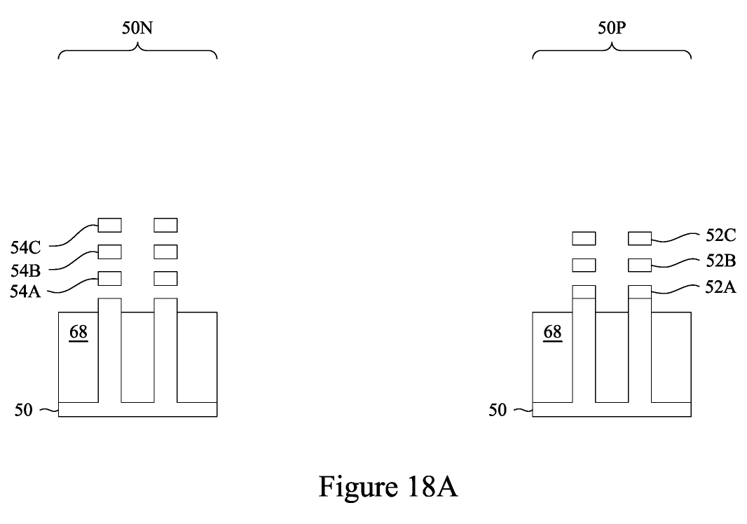

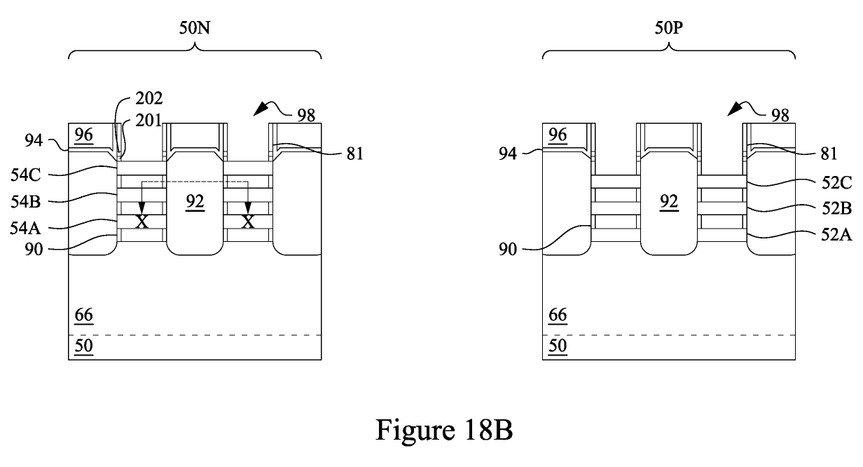

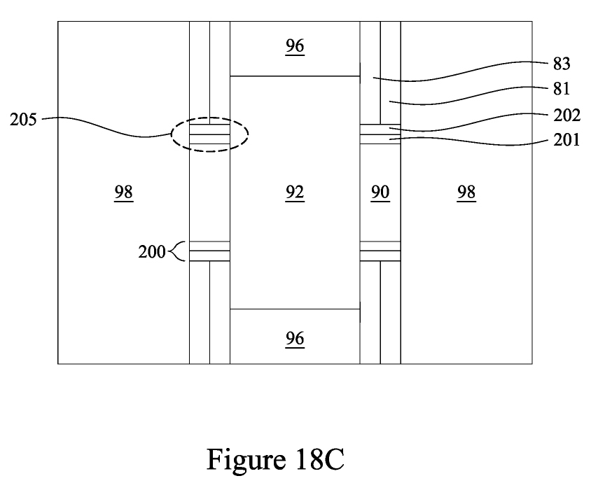

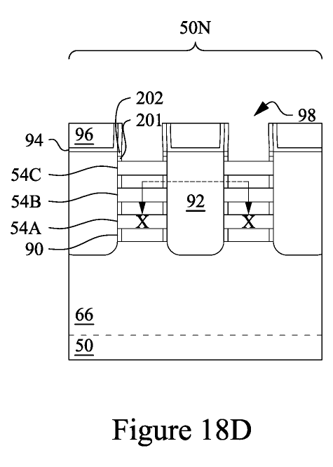

In FIGS. 18A and 18B, the first nanostructures 52 in the n-type region 50N and the second nanostructures 54 in the p-type region 50P are removed extending the second recesses 98. The first nanostructures 52 may be removed by forming a mask (not shown) over the p-type region 50P and performing an isotropic etching process such as wet etching or the like using etchants which are selective to the materials of the first nanostructures 52, while the second nanostructures 54, the substrate 50, the STI regions 58 remain relatively unetched as compared to the first nanostructures 52. In embodiments in which the first nanostructures 52 include, e.g., SiGe, and the second nanostructures 54A-54C include, e.g., Si or SiC, tetramethylammonium hydroxide (TMAH), ammonium hydroxide (NH₄OH), or the like may be used to remove the first nanostructures 52 in the n-type region 50N.

The second nanostructures 54 in the p-type region 50P may be removed by forming a mask (not shown) over the n-type region 50N and performing an isotropic etching process such as wet etching or the like using etchants which are selective to the materials of the second nanostructures 54, while the first nanostructures 52, the substrate 50, the STI regions 58 remain relatively unetched as compared to the second nanostructures 54. In embodiments in which the second nanostructures 54 include, e.g., SiGe, and the first nanostructures 52 include, e.g., Si or SiC, hydrogen fluoride, another fluorine-based etchant, or the like may be used to remove the second nanostructures 54 in the p-type region 50P.

In other embodiments, the channel regions in the n-type region 50N and the p-type region 50P may be formed simultaneously, for example by removing the first nanostructures 52 in both the n-type region 50N and the p-type region 50P or by removing the second nanostructures 54 in both the n-type region 50N and the p-type region 50P. In such embodiments, channel regions of n-type nano-FETs and p-type nano-FETS may have a same material composition, such as silicon, silicon germanium, or the like. FIGS. 23A, 23B, and 23C illustrate a structure resulting from such embodiments where the channel regions in both the p-type region 50P and the n-type region 50N are provided by the second nanostructures 54 and comprise silicon, for example.

FIG. 18C illustrates that the damage pathway block portion 205 of the hard mask layer 200 can protect the epitaxial semiconductor material of the source/drain regions, during the etch processes for removing the first nanostructures 52. In some embodiments, the damage pathway blocking portion 205 of the hard mask layer 200 protects the epitaxial material of the because the etch resistant dielectric base material 201 remains at the interface between the first inner spacers 90 and the first and second spacers 81, 83 throughout the processing of the nanowires, which includes removing the first nanostructures 52. The presence of the damage pathway block portion 205 of the hard mask layer 200 substantially blocks etchant from the process sequence for removing the first nanostructures 52 from reaching the epitaxial material of the source/drain regions 92.

FIG. 18D illustrates the removing dummy gates having curved sidewalls, particularly around the bases of the removed dummy gates. For example, FIG. 18D may correspond to the embodiments of FIG. 10C. FIG. 18D also illustrates the first nanostructures 52 in the n-type region 50N being removed extending the second recesses 98. The first nanostructures 52 may be removed by forming a mask (not shown) over the p-type region and performing an isotropic etching process such as wet etching or the like using etchants which are selective to the materials of the first nanostructures 52, while the second nanostructures 54, the substrate 50, the STI regions 58 remain relatively unetched as compared to the first nanostructures 52.

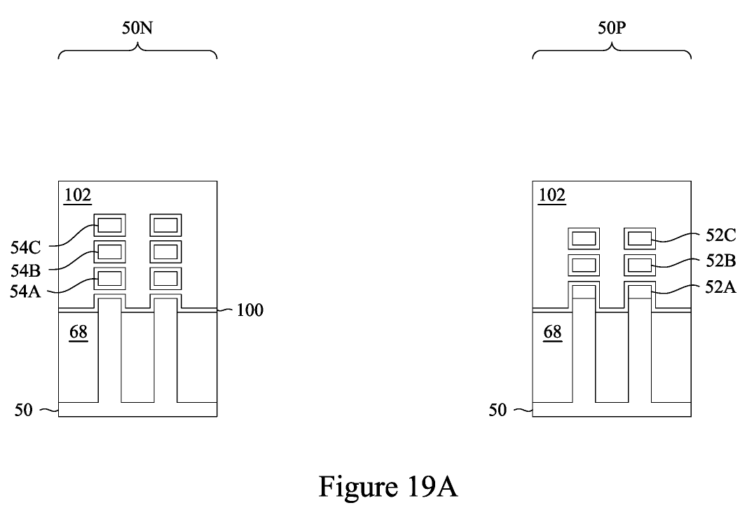

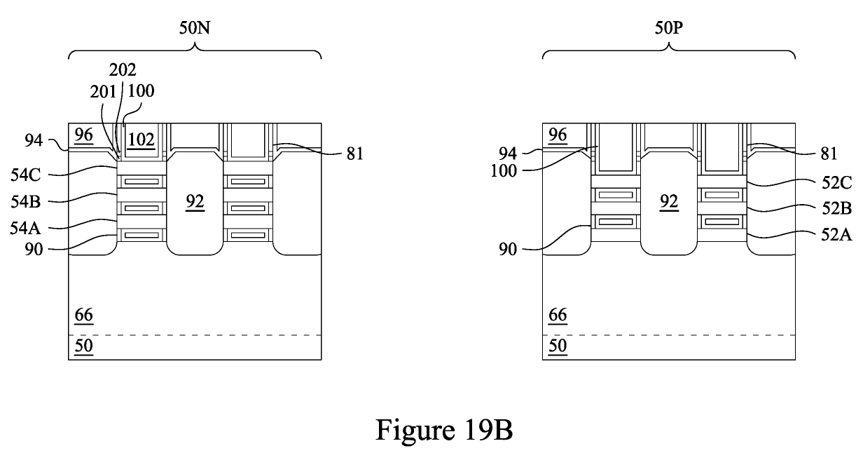

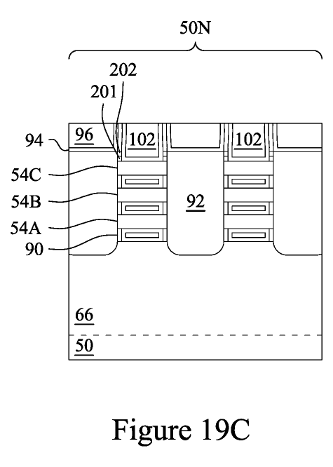

In FIGS. 19A and 19B, gate dielectric layers 100 and gate electrodes 102 are formed for replacement gates. The replacement gates may also be referred to as the functional gate structures, through with switching of the semiconductor device can be controlled. The gate dielectric layers 100 are deposited conformally in the second recesses 98. In the n-type region 50N, the gate dielectric layers 100 may be formed on top surfaces and sidewalls of the substrate 50 and on top surfaces, sidewalls, and bottom surfaces of the second nanostructures 54, and in the p-type region 50P, the gate dielectric layers 100 may be formed on top surfaces and sidewalls of the substrate 50 and on top surfaces, sidewalls, and bottom surfaces of the first nanostructures 52. The gate dielectric layers 100 may also be deposited on top surfaces of the first ILD 96, the CESL 94, the first spacers 81, and the STI regions 58.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 19A and 19B, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

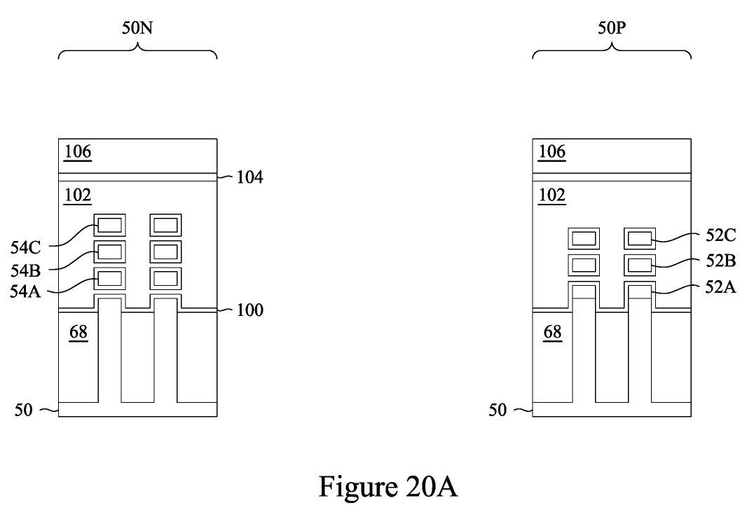

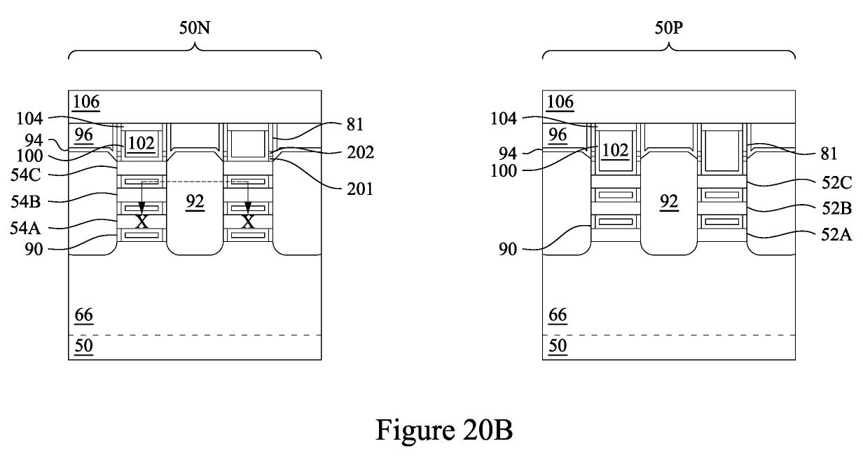

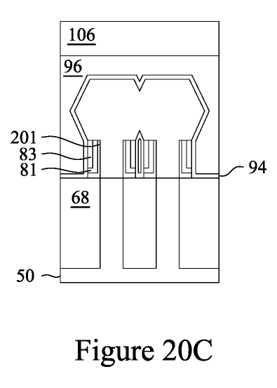

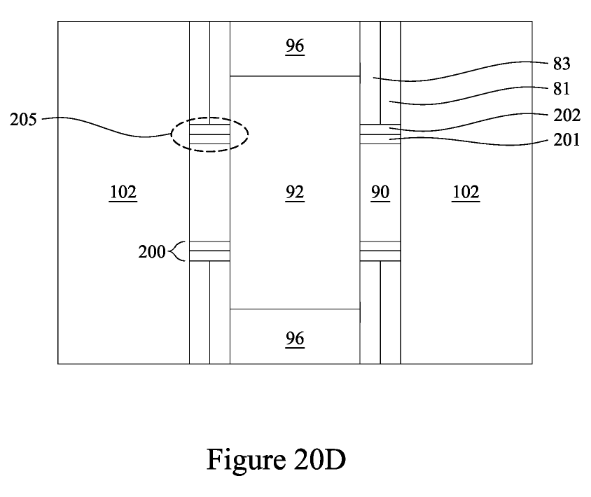

FIG. 19C illustrates replacing the dummy gates with gate structures, e.g., gate electrodes 102 and gate dielectric layers 100, in which the gate structures have curved sidewalls, particularly around the bases of the removed dummy gates. For example, FIG. 19D may correspond to the embodiments of FIG. 10C and 18D.In FIGS. 20A-20C, the gate structure (including the gate dielectric layers 100 and the corresponding overlying gate electrodes 102) is recessed, so that a recess is formed directly over the gate structure and between opposing portions of first spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 23A and 23B) penetrate through the gate mask 104 to contact the top surface of the recessed gate electrodes 102.

As further illustrated by FIGS. 20A-20D, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

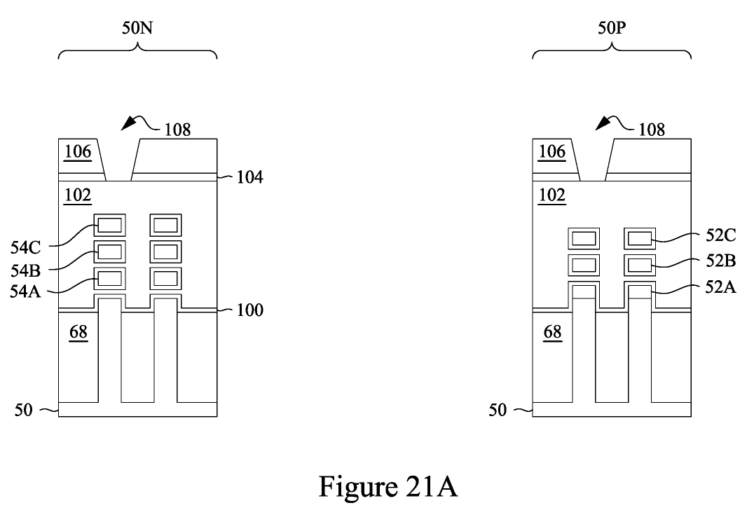

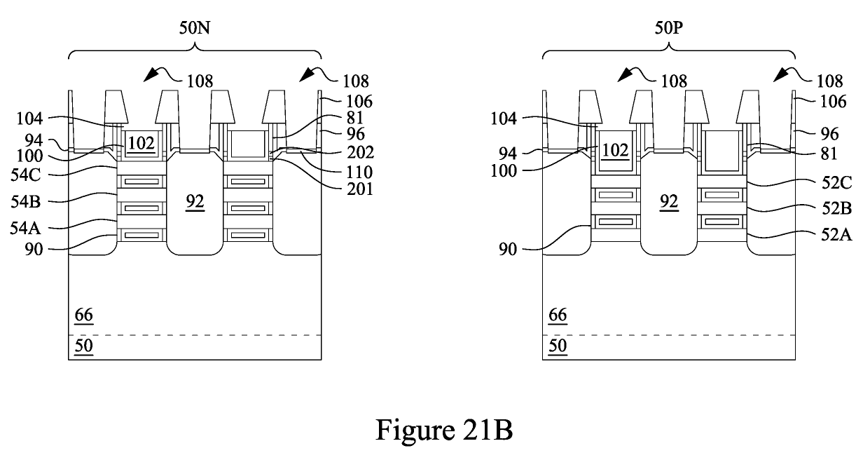

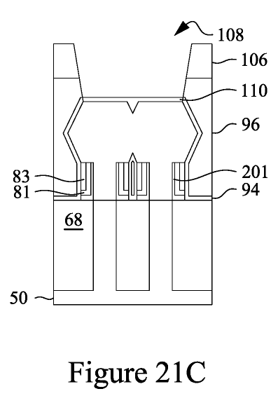

In FIGS. 21A-21C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIG. 21B illustrates the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts. After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

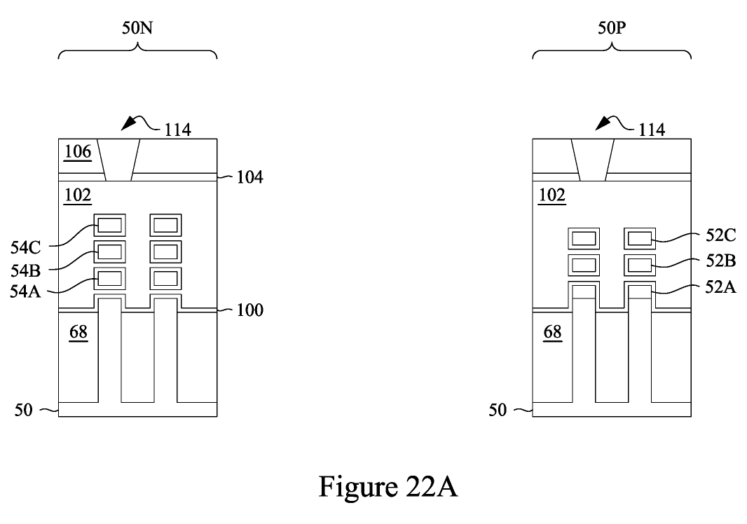

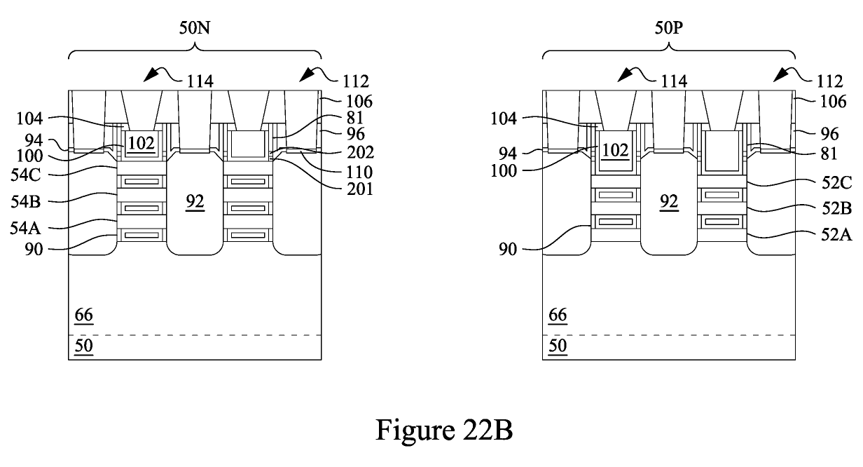

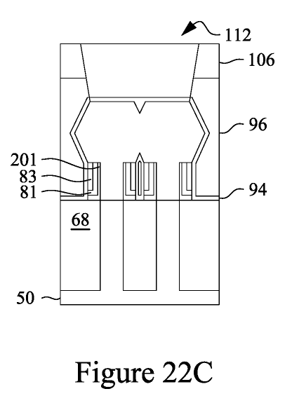

Next, in FIGS. 22A-22C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer 114 and a conductive material 118, and is electrically coupled to the underlying conductive feature (e.g., gate structure 102 and/or silicide region 110 in the illustrated embodiment). The contacts 114 are electrically coupled to the gate structure 102 and may be referred to as gate contacts, and the contacts 112 are electrically coupled to the silicide regions 110 and may be referred to as source/drain contacts. The barrier layer 114 may include titanium, titanium nitride, tantalum, tantalum nitride, or the like. The conductive material 118 may be copper, a copper alloy, silver, gold, tungsten, cobalt, aluminum, nickel, or the like. A planarization process, such as a CMP, may be performed to remove excess material from a surface of the second ILD 106.

FIGS. 23A-23C illustrate cross-sectional views of a device according to some alternative embodiments. FIGS. 23A illustrates reference cross-section A-A’ illustrated in FIG. 1. FIG. 23B illustrates reference cross-section B-B’ illustrated in FIG. 1. FIG. 231C illustrates reference cross-section C-C’ illustrated in FIG. 1. In FIGS. 23A-C, like reference numerals indicate like elements formed by like processes as the structure of FIGS. 22A-C. However, in FIGS. 23A-C, channel regions in the n-type region 50N and the p-type region 50P comprise a same material. For example, the second nanostructures 54, which comprise silicon, provide channel regions for p-type nano-FETs in the p-type region 50P and for n-type nano-FETs in the n-type region 50N. The structure of FIGS. 23A-C may be formed, for example, by removing the first nanostructures 52 from both the p-type region 50P and the n-type region 50N simultaneously; depositing the gate dielectrics 100 and the gate electrodes 102P (e.g., gate electrode suitable for a p-type nano-FET) around the second nanostructures 54 in the p-type region 50P; and depositing the gate dielectrics 100 and the gate electrodes 102N (e.g., a gate electrode suitable for a n-type nano-FET) around the second nanostructures 54 in the n-type region 50N. In such embodiments, materials of the epitaxial source/drain regions 92 may be different in the n-type region 50N compared to the p-type region 50P as explained above.

FIG. 23D is a top down view along the cross-section identified by section line X-X in FIG. 23B. FIG. 23D illustrates that the damage pathway block portion 205 of the hard mask layer 200 that protected the epitaxial semiconductor material of the source/drain regions. In some embodiments, the damage pathway blocking portion 205 of the hard mask layer 200 protects the epitaxial material of the because the etch resistant dielectric base material 201 remains at the interface between the first inner spacers 90 and the first and second spacers 81, 83 throughout the processing of the nanowires, which can include removing the first nanostructures 52. In s0me embodiments, the thin protective oxide surface 202 of the damage pathway blocking portion 205 of the hard mask layer 200 may be removed during the etch processes during the replacement gate process, e.g., the etch processes for removing the dummy gate structure, and/or the thin protective oxide surface 202 of the damage pathway blocking portion 205 of the hard mask layer 200 may be removed during the etch processes for configuring the nanowires. However, in the embodiments, in which the thin protective oxide surface 202, the dielectric base material 201 of the hard mask layer 200 remains. The thickness of the thin protective oxide surface 202 provides that any pathway that is formed by removing the thin protective oxide surface 202 is narrow, which limits the possibility of significant amounts of chemicals reaching the epitaxial material of the source/drain regions 92.

FIG. 23D illustrates the location of a damage pathway blocking portion 205 of the hard mask layer 200 present between and in direct contact with the first inner spacers 90 and the first and second spacers 81, 83. The damage pathway block portion 205 of the hard mask layer 200 substantially reduces the risk of epitaxial material damage in the source/drain regions 92, because the composition of the dielectric base material 201 for the hard mask layer 200 is resistant to being removed by the etch chemistries used in the replacement gate loop (RPG) and in the formation of nanowires. In some embodiments, the damage pathway block portion 205 of the hard mask layer 200 can reduce the size, e.g., width, of damage pathways.

The damage pathway block portion 205 of the hard mask layer 200 depicted in FIG. 23D may remain in the final device structure. In some embodiments, the hard mask layer 200 may include at least two portions that remain in the final device structure. For example, the hard mask layer 200 may include a first portion between a base surface of the gate spacer 81 (also referred to as first spacer 81) and the stack of nanostructure layers 54, as depicted in FIG. 23B. Referring back to FIG. 23D, the second portion of the hard mask layer 200 may be provided by the damage pathway block portion 205, which is present at an interface of the gate spacer, e.g., first and second spacers 81, 83, and the inner spacer 90. In some embodiments, the dielectric base material 201 of the first portion of the hard mask layer 200 at the base surface of the gate spacer 81 has a same composition as the second portion of the hard mask layer 200 at the interface of the inner spacer 90 and the gate spacer 81. For example, the composition of the dielectric base material 201 may be selected from the group consisting of aluminum oxide (AlOx), silicon carbide (SiC), silicon oxycarbonitride (SiOₓC_{y} N_{1-x-y}), silicon nitride (SiN), silicon boron nitride (SiBN), silicon carbon nitride (SiCN), silicon boron carbon nitride (SiBCN) and combinations thereof. In some embodiments, the dielectric base material 201 has a thickness ranging from 20 Å to 45 Å. In some embodiments, the hard mask layer 200 may further include the protective oxide surface 202. In some embodiments, the protective oxide surface 202 is removed from the second portion, e.g., the damage pathway block portion 205, of the hard mask layer 200 in the final device structure. In the embodiments, in which the protective oxide surface 202 is removed from the damage pathway block portion 205, and opening may be present between the gate spacer 81 and the dielectric base material 201 that is present on the inner spacer 90, wherein a width of the opening ranges from 10 Å t0 35 Å.

Embodiments may achieve advantages. For example, surface oxidized dielectric materials, such as low-k dielectric materials, can replace deposited thick oxides as a protection hard mask that avoids excessive sheet top loss that can result from by polysilicon etching processes. In addition, damage to the epitaxial material of the source/drain regions at sidewalls of the stacked semiconductor layers for the nanowire channels that can result from the oxide removal process steps of the replacement gate process can be significant avoided. By reducing the incidence of these defects, e.g., the top sheet loss, epitaxial material damage, and leakage between the gate contact and the source/drain contact, the electrical performance and yield will be significantly improved by the methods and structures of the disclosure employing the hard masks of the surface oxidized dielectric materials.

In some embodiments, the sidewall portion of the surface oxidized dielectric material (e.g., low-k dielectric material) hard mask reduces the thickness of the dielectric material of the mask, which can effectively prevent damage to the epitaxial material of the source/drain regions that can result during oxide removal processes during the replacement gate process.

In one embodiment, the oxidation treatment applied to the low-k dielectric can be controlled by O₂/noble gas mixture ratio, pressure, and power. The controllability of the oxidation process can allow for the thickness of the oxidized surface to be selected to provide a protection layer that after oxide clean process can result in a hard mask that can limit the size of the damage path to the epitaxial semiconductor material of the source/drain region.

In one embodiment, a method of forming a semiconductor device including forming a hard mask layer on exterior surfaces of a stack of nanostructure layers, the hard mask layer including a dielectric base material and a protective oxide surface; forming a dummy gate on the hard mask layer, wherein etch processes for the forming of the dummy gate are selective to the protective oxide surface; forming a gate sidewall spacer abutting the dummy gate, wherein protected portions of the hard mask layer are disposed between the gate sidewall spacer and sidewalls of the stack of nanostructures; removing the dummy gate; and removing a first set of the stack of nanostructure layers selectively to a second set of the set of nanostructure layers, wherein inner spacers are present between nanostructure layers of the second set of nanostructure layers and a portion of at least the dielectric base material from the protected portions of the hard mask layer is disposed between the inner spacer and the gate sidewall spacer. In an embodiment, the portion of the at least the dielectric base material between the inner spacers and the gate sidewall spacer protects source/drain regions from an etchant for removing the first set of the stack of nanostructure layers. In an embodiment, the portion of at least the dielectric base material between the inner spacer and the gate sidewall spacer protects the source/drain regions from an etchant for removing the dummy gate. In an embodiment, the dielectric base material has a composition selected from the group consisting of aluminum oxide (AlOx), silicon carbide (SiC), silicon oxycarbonitride (SiOxCy N1-x-y), silicon nitride (SiN), silicon boron nitride (SiBN), silicon carbon nitride (SiCN), silicon boron carbon nitride (SiBCN), and combinations thereof. In an embodiment, the protective oxide surface is formed on the dielectric base material by an oxidation process. In an embodiment, the oxidation process is selected from the group consisting of wet oxidation, dry oxidation, plasma oxidation, thermal oxidation, rapid thermal oxidation and combinations thereof. In an embodiment, the method further includes removing exposed portions of the protective oxide surface after forming the gate sidewall spacer. In an embodiment, the protective oxide surface has a thickness ranging from 10 Å to 35 Å.

In an embodiment, the method of forming a semiconductor device includes forming a dielectric base material for a hard mask layer on exterior surfaces of a stack of nanostructure layers, oxidizing a dielectric base material to form a protective oxide surface for the hard mask layer; forming a dummy gate on the hard mask layer; forming a gate sidewall spacer abutting the dummy gate, wherein protected portions of the hard mask layer are present between the gate sidewall spacer and sidewalls of the stack of nanostructures; forming source/drain regions; replacing the dummy gate and a first set of the stack of nanostructure layers with a functional gate stack, wherein a portion of at least the dielectric base material from the protected portions of the hard mask layer is disposed between source/drain regions and the functional gate stack. In an embodiment, the dielectric base material has a composition selected from the group consisting of aluminum oxide (AlOx), silicon carbide (SiC), silicon oxycarbonitride (SiOxCy N1-x-y), silicon nitride (SiN), silicon boron nitride (SiBN), silicon carbon nitride (SiCN), silicon boron carbon nitride (SiBCN) and combinations thereof. In an embodiment, the oxidation process for the oxidizing the dielectric base material is selected from the group consisting of wet oxidation, dry oxidation, plasma oxidation, thermal oxidation, rapid thermal oxidation and combinations thereof. In an embodiment, the method further includes removing exposed portions of the protective oxide surface after forming the gate sidewall spacer. In an embodiment, the protective oxide surface has a thickness ranging from 10 Å to 35 Å. In an embodiment, the portion of at least the dielectric base material between the source/drain regions and the functional gate stack is disposed between an inner spacer and the gate sidewall spacer.

In an embodiment, a semiconductor device that includes a stack of nanostructures, wherein inner spacers are present between adjacently stacked nanostructures; a gate stack around each nanostructure of the stack of nanostructures; source/drain regions on opposing sides of each nanostructure of the stack of nanostructures, the source/drain regions abutting the inner spacers; a gate spacer abutting sidewalls of the gate stack; and a hard mask layer including a dielectric base material. In some embodiments, the hard mask layer including the dielectric base material includes a first portion between a base surface of the gate spacer and the stack of nanostructure layer; and a second portion between the gate spacer and the inner spacers in a top down view, the dielectric base material of the first portion at the base surface of the gate spacer having a same composition as the dielectric base material of the second portion at an interface of the inner spacers and the gate spacer. In an embodiment, the dielectric base material has a composition selected from the group consisting of aluminum oxide (AlOx), silicon carbide (SiC), silicon oxycarbonitride (SiOxCy N1-x-y), silicon nitride (SiN), silicon boron nitride (SiBN), silicon carbon nitride (SiCN), silicon boron carbon nitride (SiBCN) and combinations thereof. In an embodiment, the dielectric base material has a thickness ranging from 20 Å to 45 Å. In an embodiment, the hard mask layer further includes a protective oxide surface between the dielectric base material and the gate spacer. In an embodiment, the hard mask layer has a thickness ranging from 20 Å to 45 Å. In an embodiment, the semiconductor device further includes opening between the gate spacer and the dielectric base material that is present on the inner spacers, wherein a width of the opening ranges from 10 Å t0 35 Å. In some embodiments, the ratio of the thickness of the protective oxide surface 202 to the thickness of the dielectric base material 201 ranges from 30% to 70%.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a stack of nanostructures over a semiconductor base material;
forming a shallow trench isolation (STI) region along a sidewall of the semiconductor base material;
forming a hard mask structure, wherein forming the hard mask structure comprises depositing a low-k dielectric material over and along sidewalls of the stack of nanostructures and along a top surface of the STI region;
depositing a dummy gate material over the hard mask structure;
patterning the dummy gate material to cover a first portion of the low-k dielectric material that is over and along the sidewalls of the stack of nanostructures;
depositing a gate spacer material over and along sidewalls of the dummy gate material and along the top surface of the STI region;
patterning the gate spacer material to define gate spacers on sidewalls of the dummy gate material and exposing a second portion of the low-k dielectric material that extends along the top surface of the STI region;
removing the second portion of the low-k dielectric material; and
replacing the dummy gate material and the first portion of the low-k dielectric material with a gate stack.

2. The method of claim 1, wherein forming the hard mask structure further comprises oxidizing an upper portion of the low-k dielectric material to provide an oxide material.

3. The method of claim 2, wherein patterning the dummy gate material comprises patterning the dummy gate material to cover a first portion of the oxide material.

4. The method of claim 3 further comprising removing a second portion of the oxide material in a same etch process as patterning the dummy gate material.

5. The method of claim 1, wherein after replacing the dummy gate material and the first portion of the low-k dielectric material with the gate stack, the gate spacers cover a third portion of the low-k dielectric material.

6. The method of claim 5 further comprising forming a source/drain region adjoining the stack of nanostructures, wherein the third portion of the low-k dielectric material is between the source/drain region and the gate stack in a plan view.

7. The method of claim 5, wherein the third portion of the low-k dielectric material extends along a sidewall of the gate stack in a plan view.

8. A method comprising:
forming a stack of nanostructures over a semiconductor base material;
forming a hard mask structure, wherein forming the hard mask structure comprises:
depositing a low-k dielectric material over and along sidewalls of the stack of nanostructures;
converting an upper portion of the low-k dielectric material to an oxide material;
forming a dummy gate structure that covers a first portion of the hard mask structure that is over and along the sidewalls of the stack of nanostructures and exposes a portion of the oxide material;
removing the portion of the oxide material;
forming gate spacers along sidewalls of the dummy gate structure, wherein the gate spacers cover a second portion of the hard mask structure and expose a portion of the low-k dielectric material;
removing the portion of the low-k dielectric material; and
removing the dummy gate structure and the first portion of the hard mask structure to define a gate recess; and
forming a gate stack in the gate recess.

9. The method of claim 8, wherein the second portion of the hard mask structure remains along a sidewall of the gate stack.

10. The method of claim 8, wherein converting the upper portion of the low-k dielectric material to the oxide material comprises a thermal oxidation process that exposes an upper surface of the low-k dielectric material to an oxygen containing gas.

11. The method of claim 10, wherein the oxygen containing gas comprises oxygen and a noble gas.

12. The method of claim 11, wherein a ratio of oxygen concentration to noble gas concentration of the oxygen containing gas is in a range of 20% to 80%.

13. The method of claim 8, wherein after converting the upper portion of the low-k dielectric material to the oxide material, a ratio of a thickness of the oxide material to a thickness of a remaining lower portion of the low-k dielectric material is in a range of 30% to 70%.

14. The method of claim 8, wherein a thickness of the oxide material is in a range of 10 Å to 35 Å.

15. A method comprising:
forming a stack of nanostructures over a semiconductor base material, wherein the stack of nanostructures comprises first nanostructures alternatingly stacked with second nanostructures;
forming a hard mask structure over and along sidewalls of the stack of nanostructures, wherein an oxygen concentration in the hard mask structure decreases in a direction towards the semiconductor base material;
forming a dummy gate structure over the hard mask structure;
forming a source/drain recess in the stack of nanostructures;
epitaxially growing a source/drain region in the source/drain recess;
removing the dummy gate structure and the second nanostructures; and
forming a gate structure over and around the first nanostructures, wherein a first portion of the hard mask structure is disposed between a sidewall of the source/drain region and a sidewall of the gate structure in a plan view.

16. The method of claim 15 further comprising:
forming a gate spacer along a sidewall of the dummy gate structure;
recessing sidewalls of the second nanostructures through the source/drain recess; and
forming inner spacers on recessed sidewalls of the second nanostructures, wherein the first portion of the hard mask structure is disposed between a first inner spacer of the inner spacers and the gate spacer in the plan view.

17. The method of claim 16, wherein the gate spacer is disposed between the source/drain region and the gate structure in the plan view.

18. The method of claim 16, wherein the first inner spacer is disposed between the first portion of the hard mask structure and a second portion of the hard mask structure in the plan view.

19. The method of claim 15, wherein forming the hard mask structure comprises:
depositing a low-k dielectric material over and along sidewalls of the stack of nanostructures; and
oxidizing an upper portion of the low-k dielectric material to form an oxide material.

20. The method of claim 19, wherein the oxide material further comprises carbon, hydrogen, nitrogen, or a combination thereof.
